(19) United States
(12) Patent Application Publication
(10) Pub. No.: US 2018/0358037 A1
(43) Pub. Date: Dec. 13, 2018

(54) SUSPENSION BOARD WITH CIRCUITS

(71) Applicant: NITTO DENKO CORPORATION, Osaka (JP)

(72) Inventors: Yoshito FUJIMURA, Osaka (JP); Hiroyuki TANABE, Osaka (JP); Yuu SUGIMOTO, Osaka (JP)

(73) Assignee: NITTO DENKO CORPORATION, Osaka (JP)

(21) Appl. No.: 15/996,897

(22) Filed: Jun. 4, 2018

(30) Foreign Application Priority Data
Jun. 9, 2017 (JP) 2017-114508

(51) Int. Cl. G11B 5/48; H05K 1/18; H05K 3/46; H05K 3/00; H05K 3/34; H05K 3/40; H05K 1/11; H05K 3/18

(52) U.S. Cl. CPC G11B 5/484; H05K 2203/0723; H05K 3/4644; H05K 3/0023; H05K 3/341; H05K 3/4007; H05K 3/4038; H05K 1/115; H05K 3/188; H05K 3/3494; H05K 2201/09027; H05K 2201/10159; H05K 2201/10083; H05K 2201/10121; H05K 1/181

(57) ABSTRACT

The suspension board with circuits can mount a slider and an electronic component, and includes a first insulating layer; a second insulating layer disposed on the first insulating layer; a third insulating layer disposed on the second insulating layer; a first conductive layer including an electronic component-connection terminal for electrically connecting with the electronic component, and a first wire disposed on the first insulating layer; a second conductive layer including a magnetic head-connection terminal for electrically connecting with a magnetic head provided in the slider, and a second wire, wherein at least a portion of the second wire is disposed on the second insulating layer. The suspension board with circuits has a pedestal supporting the slider. The pedestal includes the first insulating layer, second insulating layer, third insulating layer, and one of the first wire and second wire.

### CROSS REFERENCE TO RELATED APPLICATION

The present application claims priority from Japanese Patent Application No. 2017-114508 filed on Jun. 9, 2017, the contents of which are hereby incorporated by reference into this application.

### BACKGROUND OF THE INVENTION

### Field of the Invention

The present invention relates to a suspension board with circuits, particularly to a suspension board with circuits used for a hard disk drive.

### Description of Related Art

Conventionally, for a suspension board with circuits, a suspension board with circuits having a slider with a magnetic head at a front end portion and mounted in a hard disk drive has been known. In such a suspension board with circuits, a pedestal for supporting and fixing the slider is provided (ref: Japanese Unexamined Patent Publication No. 2012-99204).

The pedestal described in Japanese Unexamined Patent Publication No. 2012-99204 includes a first insulating base layer, a first conductive pattern formed thereon, an insulating cover layer formed on the first conductive pattern, and a front-side support layer formed on the insulating cover layer. That is, in the Japanese Unexamined Patent Publication No. 2012-99204, the front-side support layer of, for example, an insulating material, is additionally disposed at the portion supporting the slider to create a portion higher than the surrounding region to form the pedestal.

### SUMMARY OF THE INVENTION

Meanwhile, there have been proposed, for increasing memory of a disk, mounting an electronic component such as a thermally assisted device including a laser diode.

In such a suspension board with circuits, an electronic component-connection terminal for electrically connecting with electronic components and a slider-connection terminal for electrically connecting with the slider are concentrated on the front end portion of the suspension board with circuits, and therefore these terminals are disposed as a two-layered structure. That is, at the front end portion, the insulating base layer, the electronic component-connection terminal, the intermediate insulating layer, the magnetic head-connection terminal, and the insulating cover layer are laminated in the thickness direction in this sequence.

However, when the pedestal described in patent document 1 is formed on such a suspension board with circuits, that is, when the front-side support layer (insulating layer) is further provided on the insulating cover layer, the number of the insulating layers increases. To be specific, the number increases from three layers to four layers. Then, formation of the insulating layer involves heating processes such as thermosetting, and therefore there are disadvantages such as the following: thermal hysteresis increases in the suspension board with circuits, thermal damages are amplified, and reliability of the suspension board with circuits is reduced.

The present invention provides a suspension board with circuits on which an electronic component and a slider can be mounted, and in which increase in thermal hysteresis is suppressed.

The present invention [1] includes a suspension board with circuits, wherein a slider and an electronic component can be mounted thereon; the suspension board with circuits includes

a first insulating layer,

a second insulating layer disposed on the first insulating layer,

a third insulating layer disposed on the second insulating layer,

a first conductive layer including an electronic component-connection terminal for electrically connecting with the electronic component, and a first wire disposed on the first insulating layer, and

a second conductive layer including a magnetic head-connection terminal for electrically connecting with a magnetic head provided in the slider, and a second wire, wherein at least a portion of the second wire is disposed on the second insulating layer,

wherein the suspension board with circuits has a pedestal supporting the slider, and

the pedestal includes the first insulating layer, the second insulating layer, the third insulating layer, and one of the first wire and the second wire.

In this suspension board with circuits, the pedestal includes the first insulating layer, the second insulating layer, the third insulating layer, and one of the first wire and the second wire. Therefore, the front-side support layer for supporting the slider does not have to be provided on the upper side of the third insulating layer, and also the number of the insulating layer does not have to be increased to support the slider. As a result, increase in thermal hysteresis for formation of the insulating layer can be suppressed, and reliability of the suspension board with circuits can be kept.

Furthermore, the pedestal can be provided on the region where the wires (first wire or the second wire) are formed, and therefore a dedicated space for disposing the pedestal does not have to be provided. As a result, degree of freedom improves regarding where the pedestals or wires are to be disposed.

The present invention [2] includes the suspension board with circuits of [1], wherein the second conductive layer includes a plurality of second wires, the pedestal includes the first insulating layer, the second insulating layer, the plurality of second wires, and the third insulating layer in sequence.

With the suspension board with circuits, the pedestal is formed across the plurality of second wires, and therefore the slider can be stably supported.

The present invention [3] includes the suspension board with circuits of [1], wherein the first conductive layer includes a plurality of first wires, and the pedestal includes the first insulating layer, the plurality of first wires, the second insulating layer, and the third insulating layer in sequence.

With the suspension board with circuits, the pedestal is formed across the plurality of first wires, and therefore the slider can be stably supported.

With the suspension board with circuits of the present invention, increase in thermal hysteresis can be suppressed, and reliability can be kept. Furthermore, a dedicated space for disposing the pedestal does not have to be provided. As a result, degree of freedom improves regarding where the pedestals or wires are to be disposed.

### BRIEF DESCRIPTION OF THE DRAWINGS

FIG. 1 shows a plan view of the suspension board with circuits of the present invention in a first embodiment (intermediate insulating layer, support insulating layer, second conductive pattern, and insulating cover layer are omitted).

FIG. 2 shows a plan view of the suspension board with circuits shown in FIG. 1 (metal supporting board and insulating cover layer are omitted).

FIG. 3 shows a plan view of the suspension board with circuits shown in FIG. 1 (metal supporting board is omitted).

FIG. 4 shows a cross sectional view along line A-A of the suspension board with circuits shown in FIG. 1.

FIG. 5 shows a cross sectional view along line B-B of the suspension board with circuits shown in FIG. 1.

FIG. 6 shows a cross sectional view along line C-C of the suspension board with circuits shown in FIG. 1.

FIG. 7A to FIG. 7E are process diagrams for describing the method for producing a suspension board with circuits shown in FIG. 1, FIG. 7A illustrating a step for preparing a metal supporting board, FIG. 7B illustrating a step of forming an insulating base layer, FIG. 7C illustrating a step of forming a first conductive pattern, FIG. 7D illustrating a step of forming an intermediate insulating layer and a support insulating layer, and FIG. 7E illustrating a step of forming a second conductive pattern.

FIG. 8F to FIG. 8I are process diagrams for describing the method for producing the suspension board with circuits shown in FIG. 1, following FIG. 7E, FIG. 8F illustrating a step of forming an insulating cover layer, FIG. 8G illustrating a step of working a metal supporting board, FIG. 8H illustrating a step of mounting a slider unit, and FIG. 8I illustrating a step of mounting a piezoelectric element.

FIG. 9 shows a modified example of the suspension board with circuits shown in FIG. 1 (embodiment in which a portion of the wire disposed in the slider mounting region is the first conductive pattern).

FIG. 10 shows a plan view of the suspension board with circuits of the present invention in a second embodiment (intermediate insulating layer, support insulating layer, second conductive pattern, and insulating cover layer are omitted).

FIG. 11 shows a plan view of the suspension board with circuits shown in FIG. 10 (metal supporting board and insulating cover layer are omitted).

FIG. 12 shows a cross sectional view taken along line A-A of the suspension board with circuits shown in FIG. 10.

FIG. 13 shows a cross sectional view taken along line C-C of the suspension board with circuits shown in FIG. 10.

FIG. 14 shows a modified example of the suspension board with circuits shown in FIG. 10 (embodiment in which a portion of the wire disposed in the slider mounting region is second conductive pattern).

### DETAILED DESCRIPTION OF THE INVENTION

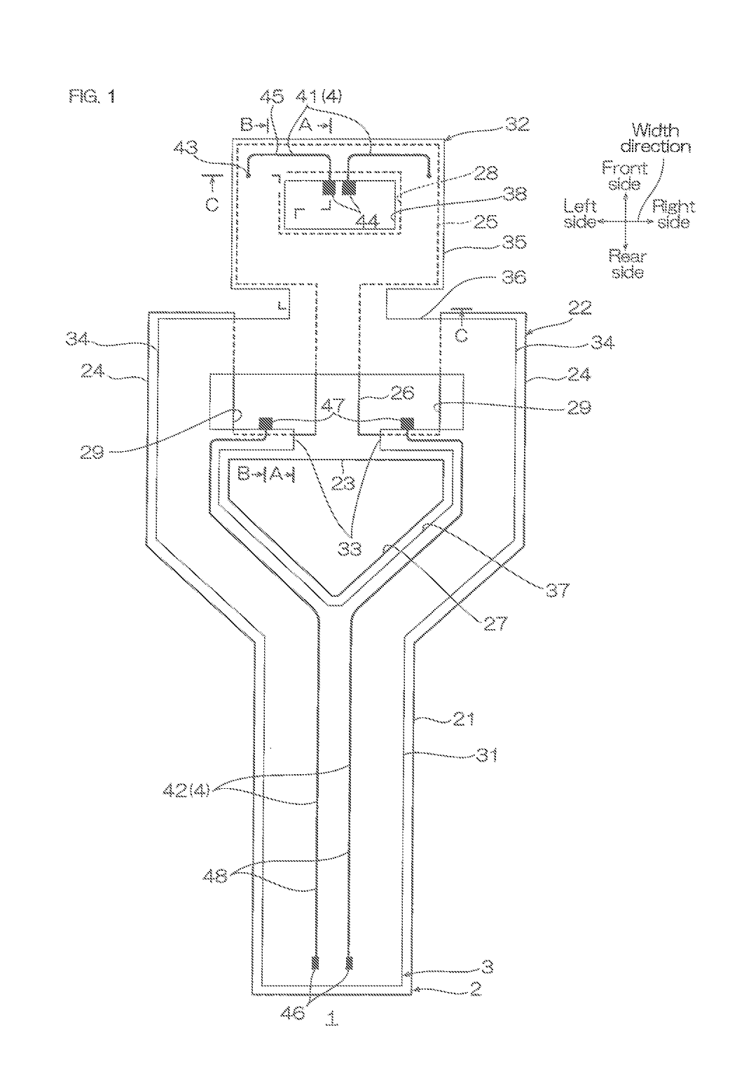

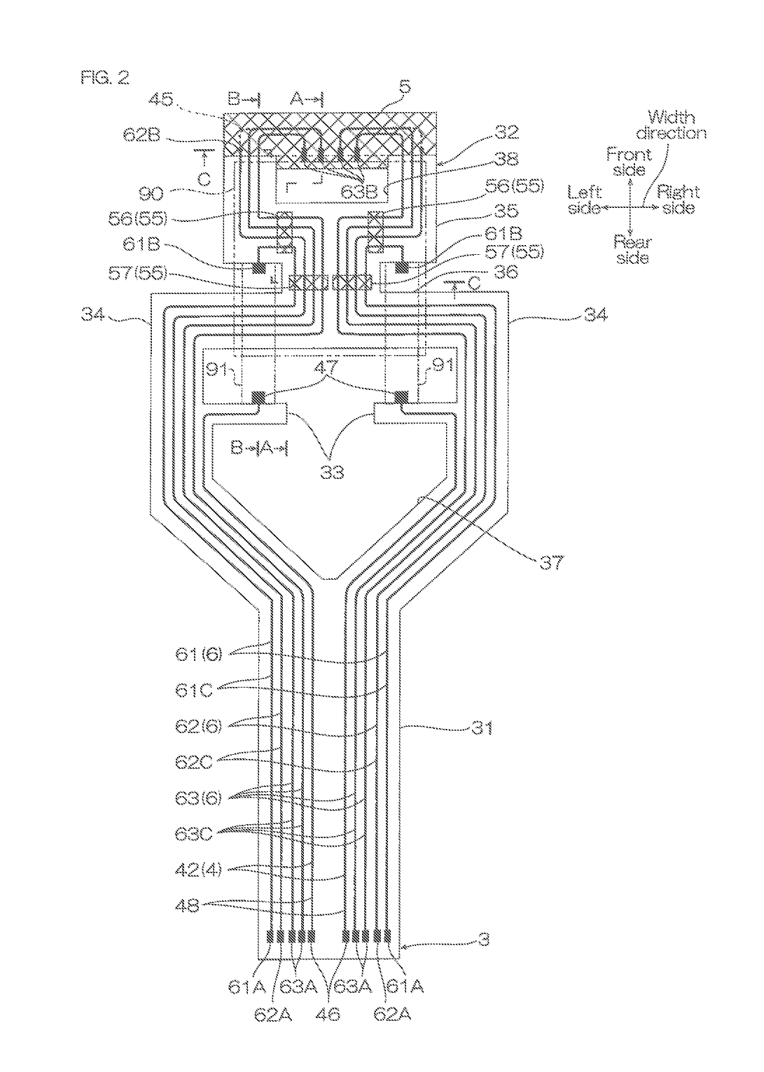

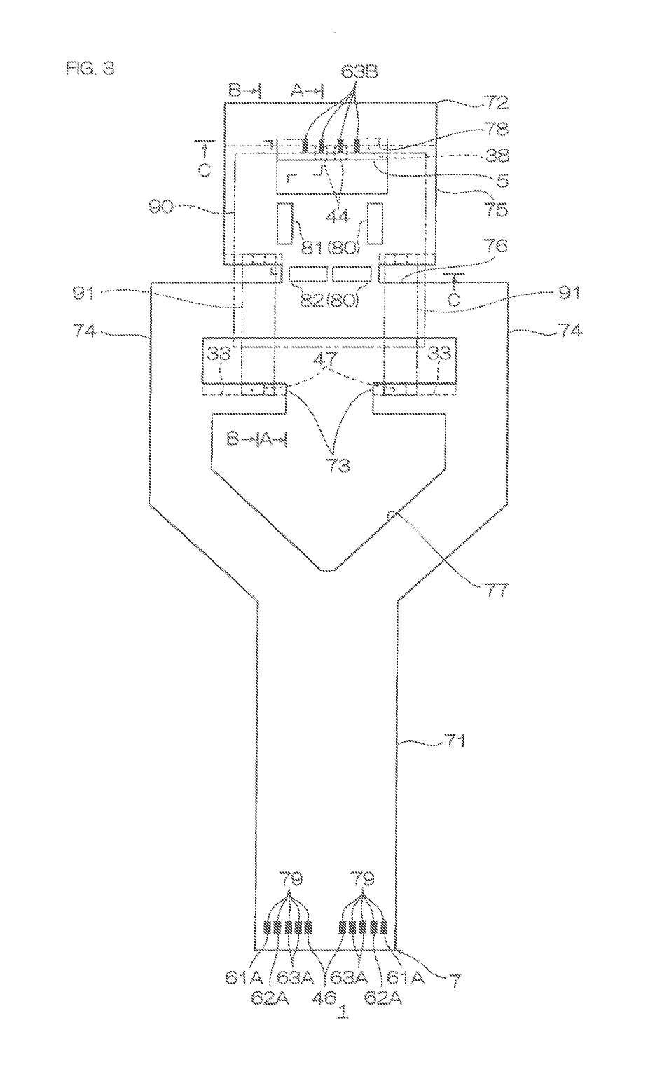

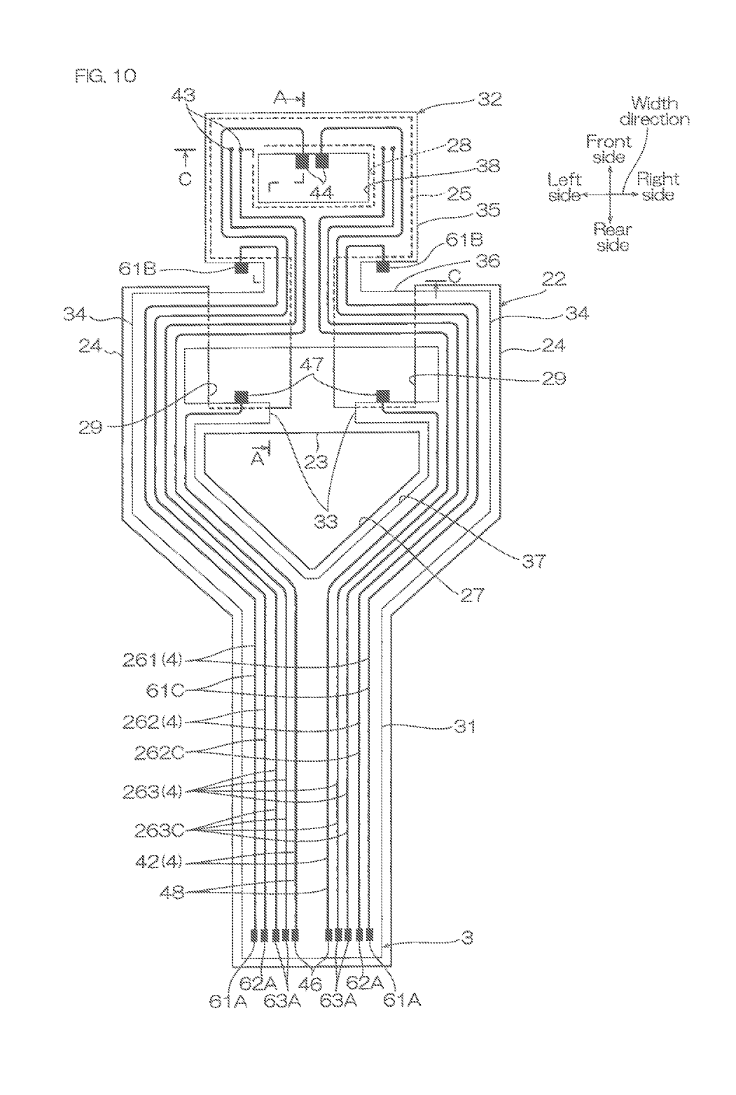

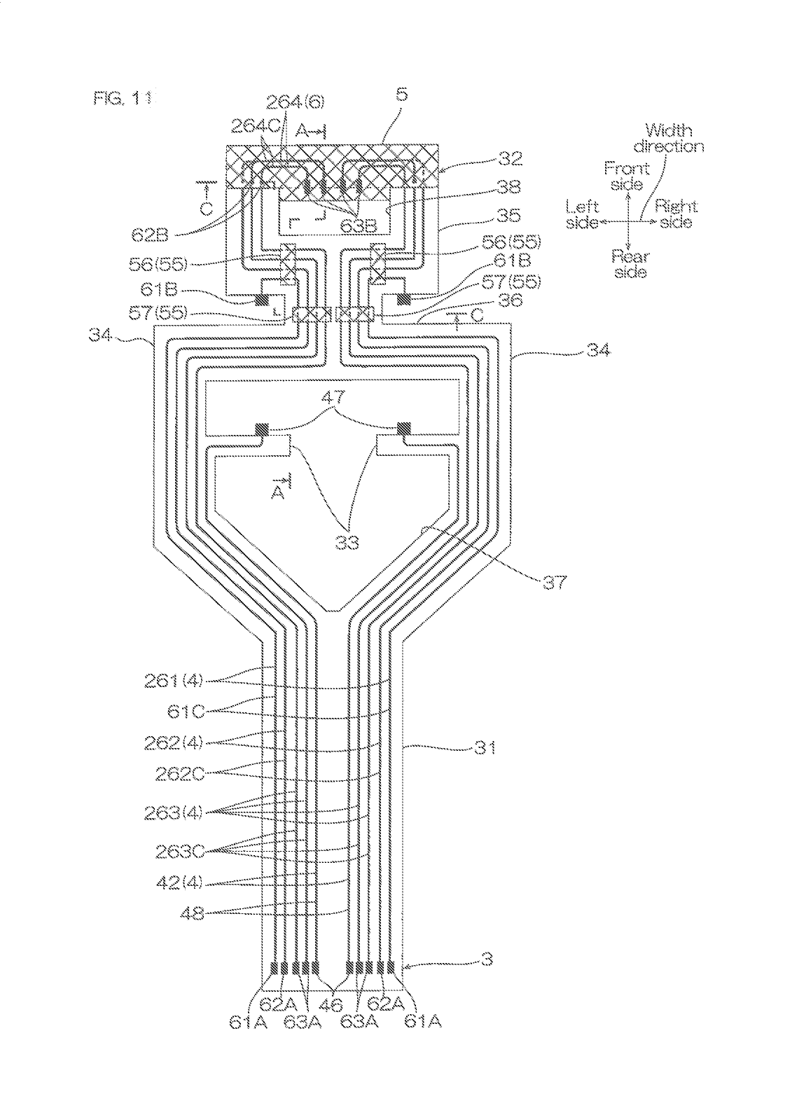

In FIG. 1, up-down direction on the plane of the sheet is front-rear direction (first direction), the upper side on the plane of the sheet is front side (one side in first direction), and the lower side on the plane of the sheet is rear side (the other side in first direction). The left-right direction on the plane of the sheet is left-right direction (width direction, second direction), the left side on the plane of the sheet is left side (one side in width direction, one side in second direction), and the right side on the plane of the sheet is right side (the other side in width direction, the other side in second direction). The paper thickness direction on the plane of the sheet is up-down direction (thickness direction, third direction), the near side on the plane of the sheet is upper side (one side in thickness direction, one side in third direction), and the far side on the plane of the sheet is lower side (the other side in thickness direction, the other side in third direction). To be specific, the directions are based on direction arrows in the figures. In FIGS. 1 and 10, the intermediate insulating layer, support insulating layer, second conductive pattern, and insulating cover layer are omitted. In FIGS. 2 and 11, the metal supporting board and insulating cover layer are omitted, and the intermediate insulating layer and support insulating layer are shown with grid hatching. In FIG. 3, the metal supporting board is omitted, and the wires of the conductive pattern are omitted.

### First Embodiment

With reference to FIG. 1 to FIG. 8, a suspension board with circuits 1 of a first embodiment of the present invention is described.

In the suspension board with circuits 1, a slider unit 12 and a piezoelectric element 13 are mounted, and the suspension board with circuits 1 is mounted on a hard disk drive (not shown) in which heat assisted method is used. In the slider unit 12, as described later, a slider 10, and a light emitting element 11 as an electronic component are mounted.

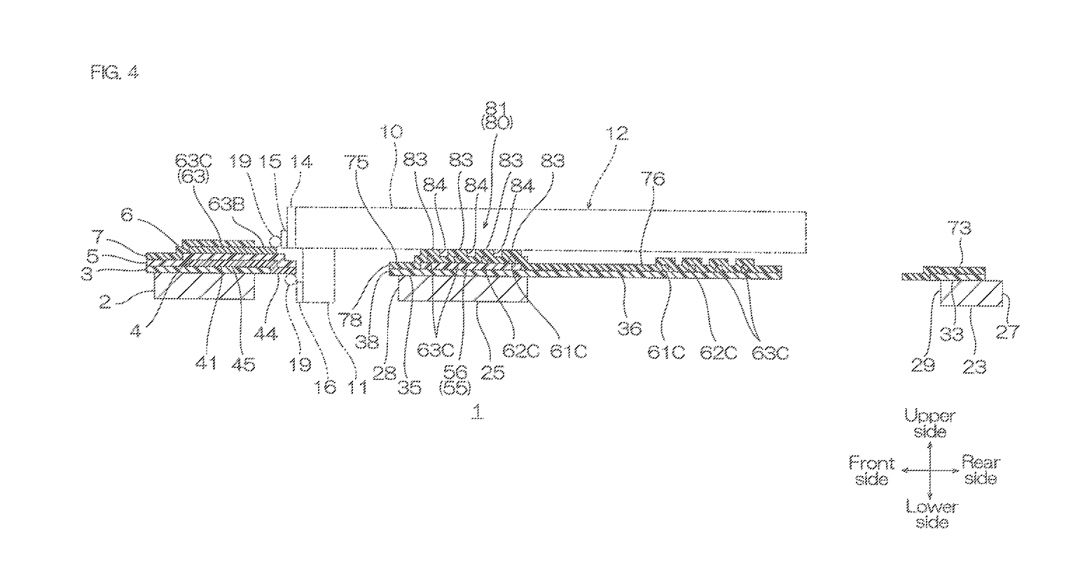

The suspension board with circuits 1 is, as shown in FIGS. 1 to 3, formed into a flat belt shape extending in front-rear direction. The suspension board with circuits 1 includes, as shown in FIGS. 4 to 6, a metal supporting board 2, an insulating base layer 3 as a first insulating layer, a first conductive pattern 4 as a first conductive layer, an intermediate insulating layer 5 as a second insulating layer, a support insulating layer 55 as a second insulating layer, a second conductive pattern 6 as a second conductive layer, and an insulating cover layer 7 as a third insulating layer.

The metal supporting board 2 is, as shown in FIG. 1, formed into a flat belt shape extending into front-rear direction, and integrally includes a main body portion 21 and a gimbal portion 22 formed at the front side of the main body portion 21.

The main body portion 21 is formed into a generally rectangular shape in plan view at the rear side portion extending into front-rear direction, and at the front side portion thereof, it is formed into a generally letter Y shape in plan view, splitting obliquely toward widthwise outer side. The main body portion 21 is supported by a load beam (not shown) of the hard disk drive when the suspension board with circuits 1 is mounted on the hard disk drive.

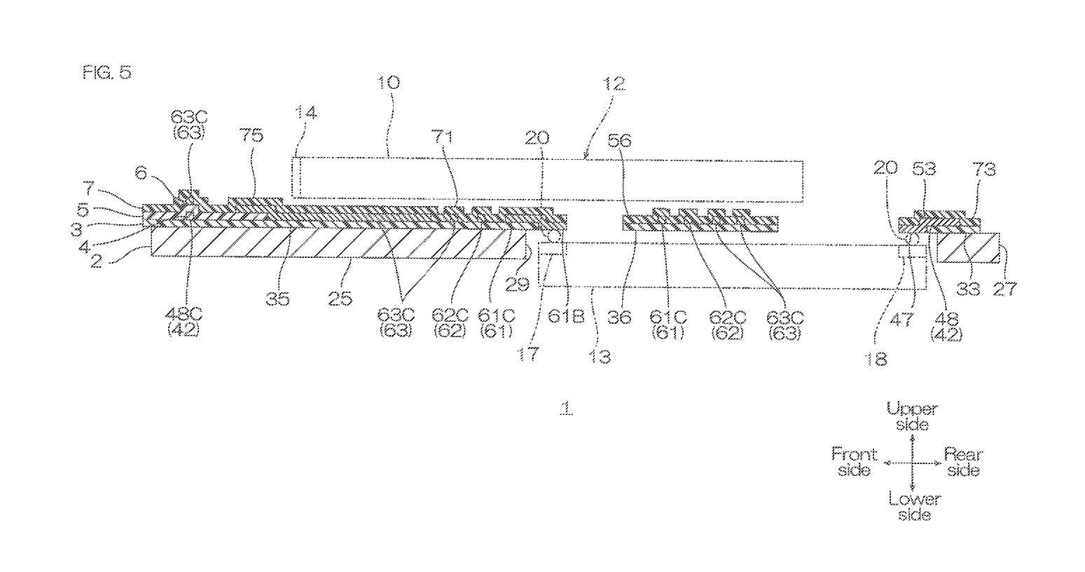

The gimbal portion 22 extends continuously from the front end of the main body portion 21 to the front side, and is formed into a generally rectangular shape having a width larger than that of the main body portion 21 in plan view. The slider unit 12 (ref: phantom line shown in FIGS. 4 to 6) and the piezoelectric element 13 (ref: phantom line shown in FIG. 5) are mounted on the gimbal portion 22.

The gimbal portion 22 includes a gimbal rear portion 23, a pair of outrigger portions 24, a mount portion 25, and a connection portion 26.

The gimbal rear portion 23 has a generally rectangular shape in plan view extending in width direction (left-right direction), and is connected in front-rear direction to the front end edge of the main body portion 21 at both widthwise outer sides. In this manner, a main body opening 27 is formed between the gimbal rear portion 23 and the main body portion 21.

The outrigger portion 24 has a generally rectangular shape in plan view extending in front-rear direction, and is formed as a pair extending linearly from the both widthwise end portions of the gimbal rear portion 23 toward the front side.

The mount portion 25 is formed into a generally rectangular shape in plan view. The mount portion 25 is disposed at the front side of the gimbal rear portion 23, in spaced apart relation from the gimbal rear portion 23. The mount portion 25 is disposed so that the rear-end edge of the mount portion 25 is positioned at the front side of the front end edge of the pair of outrigger portions 24.

A front opening 28 for mounting the slider unit 12 is formed at generally a center portion in plan view of the mount portion 25. The front opening 28 is formed into a generally rectangular shape in plan view so as to penetrate the metal supporting board 2 in thickness direction.

The connection portion 26 is formed into a generally rectangular shape in plan view extending in front-rear direction. The connection portion 26 is formed so as to bridge the front end edge of the gimbal rear portion 23 and the rear-end edge of the mount portion 25 from the widthwise center of the gimbal rear portion 23 toward the front side. The connection portion 26 is disposed in spaced apart relation at widthwise inner side of the pair of outrigger portions 24.

In this manner, a pair of center openings 29 for mounting a pair of piezoelectric elements 13 are formed between the mount portion 25 and the gimbal rear portion 23, and between the connection portion 26 and the pair of outrigger portions 24.

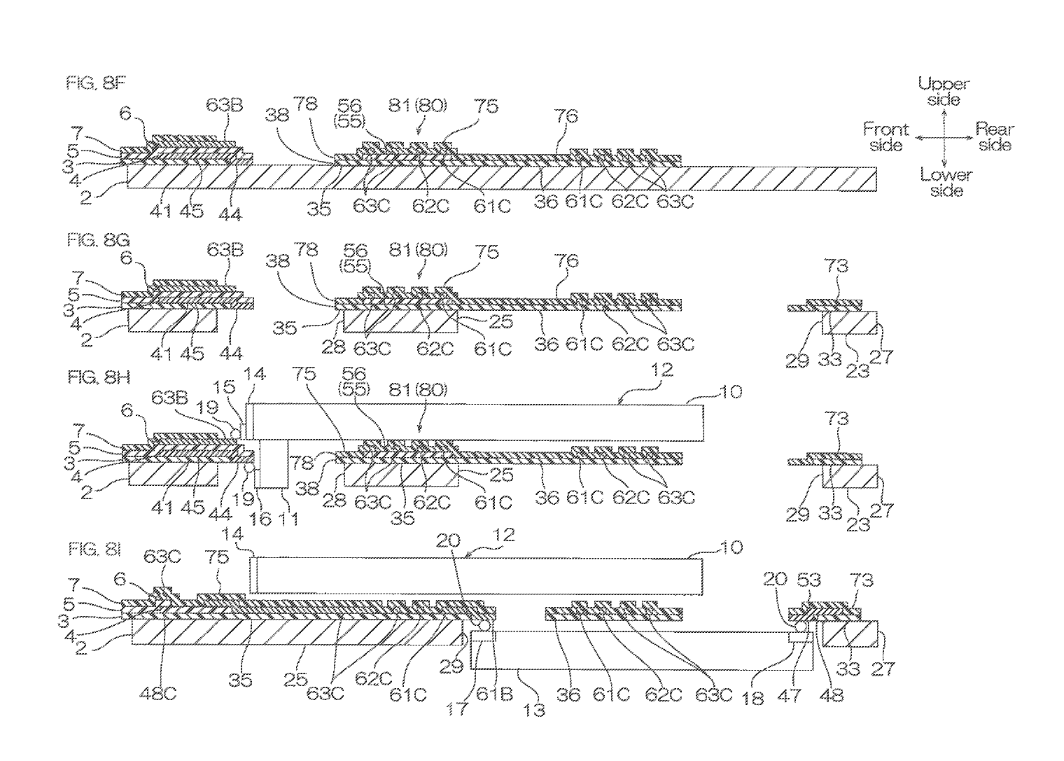

As shown in FIG. 2, FIG. 3, and FIG. 8H, the region that overlaps with the slider unit 12 is the slider mounting region 90 when the slider unit 12 is projected in thickness direction at the time of mounting it on the suspension board with circuits 1. The slider mounting region 90 is, specifically, a region from the front side portion of the front opening 28 (to be more specific, rear-end edge of the magnetic head-connection terminals 63B to be described later) to the rear side portion of the connection portion 26 in front-rear direction of the metal supporting board 2, and in the width direction of the metal supporting board 2, is a region positioned at the widthwise inner side of the mount portion 25.

As shown in FIG. 2, FIG. 3, and FIG. 8I, a piezoelectric element mounting region 91 is a region overlapping with the pair of piezoelectric elements 13 when the pair of piezoelectric elements 13 are projected in thickness direction upon mounting it on the suspension board with circuits 1. A plurality of (two) piezoelectric element mounting regions 91 are defined in spaced apart relation from each other in width direction. To be specific, the piezoelectric element mounting regions 91 are regions positioned at generally a center portion in plan view of the pair of center openings 29 (to be more specific, from front end edge of the front piezoelectric element connection terminal 61B to rear-end edge of the rear piezolectric element connection terminal 47 to be described later).

The metal supporting board 2 is formed from, for example, metal materials such as stainless steel, 42alloy, and aluminum. Preferably, it is formed from stainless steel.

The metal supporting board 2 has a thickness of, for example, 5 μm or more, preferably 10 μm or more, and for example, 35 μm or less, preferably 30 μm or less.

The insulating base layer 3 is disposed at, as shown in FIG. 1, the upper face (surface on one side in thickness direction) of the metal supporting board 2. The insulating base layer 3 integrally includes a main body portion insulating base layer 31 corresponding to the main body portion 21, and a gimbal portion insulating base layer 32 corresponding to the gimbal portion 22.

The main body portion insulating base layer 31 extends from the rear end portion toward the front side in the main body portion 21 so as to correspond to the pattern of a first conductive pattern 4 (described later) and a second conductive pattern 6 (described later) to be formed, and is formed into a generally letter Y shape in plan view, splitting obliquely toward the front side and widthwise outer side at the front end portion of the main body portion 21.

The gimbal portion insulating base layer 32 includes a pair of rear insulating base layers 33 corresponding to the gimbal rear portion 23, a pair of outer insulating base layers 34 corresponding to the pair of outrigger portions 24, a front-insulating base layer 35 corresponding to the mount portion 25, and an inner-insulating base layer 36 corresponding to the connection portion 26.

The pair of rear insulating base layers 33 are formed into a generally rectangular shape in plan view in spaced apart relation from each other in width direction so as to extend inward continuously from the front end edge of the main body portion insulating base layer 31.

The pair of outer insulating base layers 34 are formed into a generally rectangular shape in plan view so as to extend toward the front side continuously from the front end edge of the widthwise outside portion of the pair of rear insulating base layer 33 in spaced apart relation from each other in width direction.

The front-insulating base layer 35 is formed into a generally rectangular shape in plan view. The front-insulating base layer 35 is formed so that its peripheral edge is slightly outside of the peripheral edge of the mount portion 25 of the metal supporting board 2. That is, the front end edge of the front-insulating base layer 35 is positioned at the front side of the front end edge of the mount portion 25, and the rear-end edge of the front-insulating base layer 35 is positioned at the rear side of the rear-end edge of the mount portion 25, and the left-end edge of the front-insulating base layer 35 is positioned at the left side of the left-end edge of the mount portion 25, and the right-end edge of the front-insulating base layer 35 is positioned at the right side of the right-end edge of the mount portion 25.

At a generally center in plan view of the front-insulating base layer 35, a front insulating base opening 38 is formed.

The front insulating base opening 38 is formed into a generally rectangular shape in plan view at the portion overlapping with the front opening 28 when projected in thickness direction so as to penetrate the front-insulating base layer 35 in thickness direction.

The front insulating base opening 38 is formed so that its peripheral edge is slightly inside the peripheral edge of the front opening 28. That is, the front end edge of the front insulating base opening 38 is positioned at the rear side of the front end edge of the front opening 28, the rear-end edge of the front insulating base opening 38 is positioned at the front side of the rear-end edge of the front opening 28, the left-end edge of the front insulating base opening 38 is positioned at the right side of the left-end edge of the front opening 28, and the right-end edge of the front insulating base opening 38 is positioned at the left side of the right-end edge of the front opening 28.

The inner-insulating base layer 36 is formed into a generally inversed letter T shape in plan view so as to bridge the front-insulating base layer 35 and the pair of outer insulating base layers 34. That is, the inner-insulating base layer 36 is formed so that it extends from the rear-end edge of the front-insulating base layer 35 at the widthwise center toward the rear side, splits widthwise and outward into two along the way, and reaches the widthwise inner end edge of the front side portion of the pair of outer insulating base layers 34.

In the insulating base layer 3, a rear insulating base opening 37 is formed between the main body portion insulating base layer 31, the pair of the rear insulating base layers 33, the pair of outer insulating base layers 34, and the inner-insulating base layer 36. The rear insulating base opening 37 is formed so as to include the main body opening 27 when projected in thickness direction.

The insulating base layer 3 is formed from insulating materials such as, for example, synthetic resin including polyimide resin, polyamide-imide resin, acrylic resin, polyethernitrile resin, polyether sulfone resin, polyethylene terephthalate resin, polyethylenenaphthalate resin, and polyvinyl chloride resin. Preferably, it is formed from polyimide resin.

The insulating base layer 3 has a thickness of, for example, 1 μm or more, preferably 3 μm or more, and for example, 35 μm or less, preferably 33 μm or less.

As shown in FIG. 1, the first conductive pattern 4 is disposed at the upper face of the insulating base layer 3. The first conductive pattern 4 includes a light emitting element front connection circuit 41 and a rear piezoelectric element connection circuit 42.

The light emitting element front connection circuit 41 includes a lower side connecting portion 43, a light emitting element connection terminal 44 as the electronic component-connection terminal, and a first front power source wire 45 as a first wire.

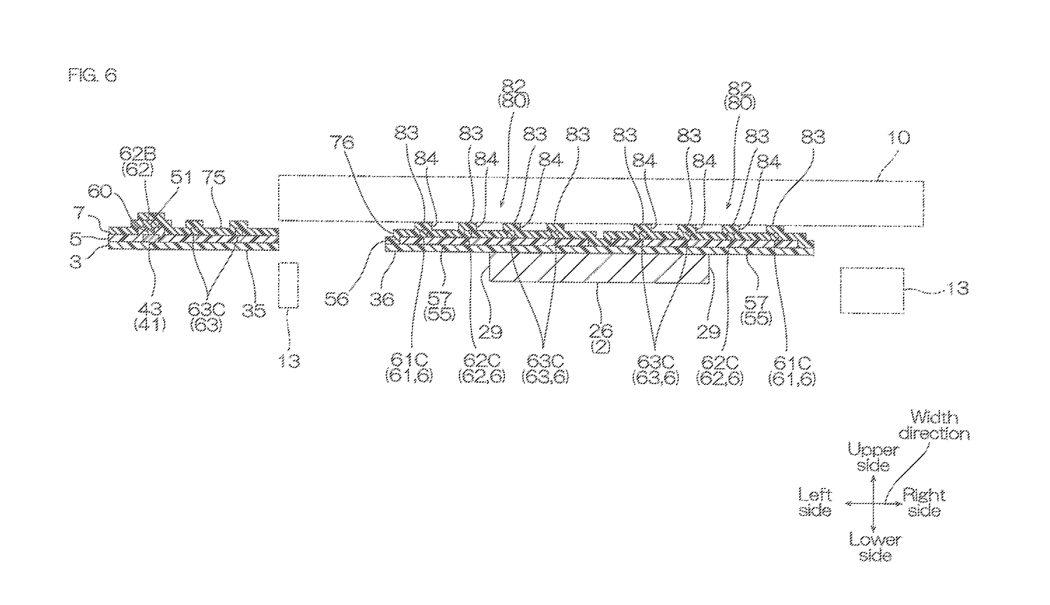

A plurality of (two) lower side connecting portions 43 are provided at the front side portion of the front-insulating base layer 35, at widthwise outside in spaced apart relation from each other in width direction. The lower side connecting portions 43 are formed into a generally circular shape (circle land shape) in plan view, and is disposed so as to include a through hole 51 (described later) when projected in thickness direction. The upper end portion of the lower side connecting portion 43 is continuous with, as shown in FIG. 6, the lower end of the via conductive portion 60 (described later).

A plurality of (two) light emitting element connection terminals 44 are provided, and are disposed at the front end portion of the front insulating base opening 38. To be specific, the light emitting element connection terminals 44 are formed into a generally rectangular shape in plan view so as to extend from the front end edge of the front insulating base opening 38 to the rear side, and are disposed in spaced apart relation from each other in width direction. The light emitting element connection terminals 44 are formed, as shown in FIG. 4, so as to slightly extend from the front end edge of the front insulating base opening 38 toward the lower side, and then extend toward the rear side.

A plurality of (two) first front power source wires 45 are provided, and are disposed one by one in spaced apart relation from each other in width direction at the front side portion of the front-insulating base layer 35. The first front power source wire 45 is formed so that one end thereof is continuous with the lower side connecting portion 43, and the other end thereof is continuous with the light emitting element connection terminal 44. To be specific, the first front power source wire 45 is formed so as to slightly extend from the lower side connecting portion 43 along the peripheral end of the front-insulating base layer 35 toward the front side at the front side portion of the front-insulating base layer 35; bend inward at its front end portion; turn back to the rear side at inner portion; and reach the light emitting element connection terminal 44.

The first front power source wire 45 electrically connects the lower side connecting portion 43 and the light emitting element connection terminal 44.

The rear piezoelectric element connection circuit 42 includes second power source terminals 46, a rear piezoelectric element connection terminal 47, and a second power source wire 48.

A plurality of (two) second power source terminals 46 are provided at a rear end portion of the main body portion insulating base layer 31. Of the plurality of (ten) terminals, the second power source terminals 46 are provided one by one at the rear end portion of the main body portion insulating base layer 31, at widthwise innermost side in spaced apart relation from each other. The second power source terminals 46 are formed into a generally rectangular shape in plan view. The second power source terminals 46 are electrically connected to a power source for piezoelectric elements (not shown).

A plurality of (two) rear piezoelectric element connection terminals 47 are provided, and are disposed at the rear end portion of the pair of piezoelectric elements mounting regions 91.

To be specific, the rear piezoelectric element connection terminals 47 are formed into a generally rectangular shape in plan view so as to extend from the front end edge and widthwise inner side of the rear insulating base layer 33 in plan view toward the front side, and are disposed in spaced apart relation from each other in width direction. The rear piezoelectric element connection terminals 47 are formed, as shown in FIG. 5, so as to slightly extend from the front end edge of the rear insulating base layer 33 toward the lower side, and then extend toward the front side.

A plurality of (two) second power source wires 48 are provided, as shown in FIG. 1. The second power source wires are 48 disposed one by one, of the plurality of (ten) wires provided in the main body portion insulating base layer 31, at widthwise innermost side in spaced apart relation from each other in width direction. The second power source wires 48 are formed so that one end thereof is continuous with the second power source terminals 46, and the other end thereof is continuous with the rear piezoelectric element connection terminal 47. To be specific, the second power source wires 48 are formed so as to extend from the second power source terminals 46 toward the front side in the main body portion insulating base layer 31; bend widthwise outwardly at the front end portion of the main body portion insulating base layer 31; bend frontward at its both widthwise end portions; bend widthwise inward at the rear insulating base layer 33; bend frontward at the inner portion of the rear insulating base layer 33; and reach the rear piezoelectric element connection terminal 47.

The second power source wires 48 electrically connect the second power source terminals 46 and the rear piezoelectric element connection terminals 47. The second power source wires 48 supply electricity from the power source for piezoelectric elements (not shown) to the piezoelectric element 13 through the second power source terminals 46.

The first conductive pattern 4 is formed from, for example, metal conductive materials such as copper, nickel, gold, solder, or alloys thereof, preferably, copper.

The first conductive pattern 4 has a thickness of, for example, 1 μm or more, preferably 3 μm or more, and for example, 25 m or less, preferably 20 μm or less.

The wires (45, 48) have a width of, for example, 5 μm or more, preferably 8 μm or more, and for example, 200 μm or less, preferably 100 μm or less.

The terminals (44, 46, 47) have a width and a length (length in front-rear direction) of, for example, 10 μm or more, preferably 20 μm or more, and for example, 1000 μm or less, preferably 800 μm or less.

The lower side connecting portions 43 have a diameter of, for example, 30 pun or more, preferably 40 μm or more, and for example, 200 μm or less, preferably 150 μm or less.

The intermediate insulating layer 5 is disposed on the upper face of the insulating base layer 3 and the first conductive pattern 4, as shown in FIG. 2 and FIGS. 4 to 6. To be specific, the intermediate insulating layer 5 is disposed on the upper face of the insulating base layer 3 so as to cover the upper face and the side faces of the first front power source wire 45.

The intermediate insulating layer 5 is formed into a generally rectangular shape in plan view so as to be generally the same as the front side portion of the front-insulating base layer 35 in plan view. To be specific, the front end edge of the intermediate insulating layer 5 coincides with the front end edge of the front-insulating base layer 35, and the widthwise outer end edges (left-end edge and right-end edge) of the intermediate insulating layer 5 coincide with the widthwise outer end edges (left-end edge and right-end edge) of the front-insulating base layer 35. The rear-end edge of the widthwise outside portions of the intermediate insulating layer 5 is positioned at a center in front-rear direction of the front-insulating base layer 35, and is positioned at a rear side of the lower side connecting portion 43. The rear-end edge of the widthwise center portion of the intermediate insulating layer 5 is positioned at the rear side of the front end edge of the front insulating base opening 38, and coincides with the rear-end edge of the light emitting element connection terminals 44 (ref: FIG. 3). In this manner, the intermediate insulating layer 5 covers the upper face and the side faces of the light emitting element connection terminals 44.

In the intermediate insulating layer 5, as shown in FIGS. 2 and 6, a plurality of (two) through holes 51 penetrating the intermediate insulating layer 5 in thickness direction are formed. The through holes 51 are disposed in spaced apart relation from each other in width direction at the widthwise outside portion of the intermediate insulating layer 5. The through holes 51 are formed into a generally circular shape in plan view when projected in thickness direction at a portion overlapping with the lower side connecting portion 43, having a smaller diameter than that of the lower side connecting portion 43. That is, the through holes 51 are formed so as to be included in the lower side connecting portion 43 when projected in thickness direction.

A via conductive portion 60 is provided in the through holes 51. To be specific, the via conductive portion 60 is disposed so as to fill the entire through holes 51. The via conductive portion 60 is formed into a cylindrical shape having a smaller diameter than that of the lower side connecting portion 43.

The via conductive portion 60 is formed from, for example, a metal conductive material that is the same as that of the first conductive pattern 4, preferably, formed from copper.

The intermediate insulating layer 5 is formed from the same insulating material as that of the insulating base layer 3. The intermediate insulating layer 5 has a thickness of, for example, 1 μm or more, preferably 3 μm or more, and for example, 40 μm or less, preferably 10 μm or less.

The support insulating layer 55 is the slider mounting region 90, and is disposed on the upper face of the insulating base layer 3. The support insulating layer 55 includes a plurality of (four) support insulating portions. That is, the support insulating layer 55 includes a plurality of (two) first support insulating portions 56, and a plurality of (two) second support insulating portions 57 disposed at the rear side thereof.

The plurality of first support insulating portions 56 are disposed in spaced apart relation in width direction at rear side portion of the front-insulating base layer 35. The first support insulating portions 56 are formed into a sheet shape extending in surface direction (front-rear direction and width direction). The first support insulating portions 56 are disposed so as to overlap with the plurality of (four) wires (61C, 62C, 63C) when projected in thickness direction.

To be specific, on the upper face of the first support insulating portions 56, a third power source wire 61C, a first rear power source wire 62C, and two signal wires 63C to be described later are disposed, and the first support insulating portions 56 are formed into a generally rectangular shape in plan view extending in front-rear direction, i.e., a direction crossing (orthogonal) the direction these wires extend. That is, the first support insulating portions 56 are disposed below these wires across the plurality of (four) wires (61C, 62C, 63C) in front-rear direction.

The plurality of second support insulating portions 57 are disposed in spaced apart relation in width direction at the front side portion of the inner-insulating base layer 36. The second support insulating portions 57 are formed into a sheet shape extending in the surface direction. The second support insulating portions 57 are disposed so as to overlap the plurality of (four) wires (61C, 62C, 63C) when projected in thickness direction. To be specific, on the upper face of the second support insulating portions 57, the third power source wire 61C, first rear power source wires 62C, and two signal wires 63C are disposed, and the second support insulating portions 57 are formed into a generally rectangular shape in plan view in width direction, i.e., a direction crossing (orthogonal) the direction these wires extend. That is, the second support insulating portions 57 are disposed below these wires across the plurality of (four) wires (61C, 62C, 63C) in width direction.

The support insulating layer 55 is not continuous with the intermediate insulating layer 5, and is independent from the intermediate insulating layer 5.

The support insulating layer 55 is formed simultaneously with and from the same insulating material with the insulating material forming the intermediate insulating layer 5. The thickness of the support insulating layer 55 is the same as the thickness of the intermediate insulating layer 5. To be specific, for example, the thickness is, 1 μm or more, preferably 3 μm or more, and for example, 40 μm or less, preferably 10 μm or less.

The support insulating layer 55 has a surface direction length (length in front-rear direction and length in width direction) in maximum of, for example, 5 μm or more, preferably 10 μm or more, and for example, 5000 μm or less, preferably 3000 μm or less, more preferably 1000 μm or less.

At least a portion of the second conductive pattern 6 is disposed at, as shown in FIG. 2 and FIGS. 4 to 6, the upper face of the intermediate insulating layer 5 and the support insulating layer 55. The second conductive pattern 6 includes a front piezoelectric element connection circuit 61, a light emitting element rear side connection circuit 62, and a magnetic head-connection circuit 63.

The front piezoelectric element connection circuit 61 includes a third power source terminal 61A, a front piezoelectric element connection terminal 61B, and a third power source wire 61C.

A plurality of (two) third power source terminals 61A are provided (two) at a rear end portion of the main body portion insulating base layer 31. Of the plurality of (ten) terminals provided on the main body portion insulating base layer 31, the third power source terminals 61A are disposed one by one at the widthwise outermost sides in spaced apart relation from each other. The third power source terminals 61A are formed into a generally rectangular shape in plan view. The third power source terminals 61A are electrically connected to a power source for piezoelectric elements (not shown).

A plurality of (two) front piezoelectric element connection terminals 61B are provided, and are disposed at a front end portion of the pair of piezoelectric elements mounting regions 91. To be specific, the front piezoelectric element connection terminals 61B are formed into a generally rectangular shape in plan view so as to extend from the rear-end edge of the widthwise outside portion of the front-insulating base layer 35 to the rear side in plan view, and are disposed in spaced apart relation from each other in width direction. As shown in FIG. 5, the front piezoelectric element connection terminals 61B are formed so as to slightly extend to the lower side from the rear-end edge of the front-insulating base layer 35, and then extend to the rear side.

A plurality of (two) third power source wires 61C are provided. Of the plurality of (ten) wires provided in the insulating base layers 3, the third power source wires 61C are disposed one by one at the widthwise outermost side in spaced apart relation from each other in width direction. The third power source wires 61C are formed so that one end thereof is continuous with the third power source terminals 61A, and the other end thereof is continuous with the front piezoelectric element connection terminals 61B. To be specific, the third power source wires 61C are formed so as to extend from the third power source terminals 61A along the second power source wires 48 in the main body portion insulating base layer 31; extend to the front side in the rear insulating base layer 33 and the outer insulating base layer 34; bend widthwise inner side in the front end portion of the outer insulating base layer 34; bend to the front side at widthwise center of the inner-insulating base layer 36; and bend to the widthwise outside at the rear end portion of the front-insulating base layer 35; then turn back to the rear side along the way in width direction of the rear end portion; and reach the front piezoelectric element connection terminals 61B.

In the pedestal region (that is, region where the support insulating layer 55 is disposed when projected in thickness direction), the third power source wires 61C are disposed on the upper face of the support insulating layer 55, and in the region other than the pedestal region, the third power source wires 61C are disposed on the upper face of the insulating base layer 3.

The third power source wires 61C electrically connect the third power source terminals 61A to the front piezoelectric element connection terminals 61B. The third power source wires 61C supply electric power from the power source for piezoelectric elements to the piezoelectric element 13 through the third power source terminals 61A.

The light emitting element rear side connection circuit 62 includes first power source terminals 62A, upper side connecting portions 62B, and first rear power source wires 62C.

The plurality of (two) first power source terminals 62A are provided at the rear end portion of the main body portion insulating base layer 31. The first power source terminals 62A are disposed one by one at widthwise inner side of the plurality of (two) third power source terminals 61A in spaced apart relation from each other. The first power source terminals 62A are electrically connected to a power source for light emitting element (not shown).

The plurality of (two) upper side connecting portions 62B are provided, and are disposed at widthwise outside of the intermediate insulating layer 5 in spaced apart relation from each other in width direction. The upper side connecting portions 62B are formed into a generally circular shape (circle land shape) in plan view, and are disposed so as to include the through hole 51 (described later) when projected in thickness direction. The lower end portion of the upper side connecting portions 62B is, as shown in FIG. 6, continuous with the upper end of the via conductive portion 60.

The plurality of (two) first rear power source wires 62C are provided, as shown in FIG. 2. The first rear power source wires 62C are disposed widthwise inner side of the plurality of (two) third power source wires 61C, to be more specific, the first rear power source wires 62C are disposed one by one adjacently widthwise inner side of the plurality of (two) third power source wires 61C in spaced apart relation from each other in width direction. The first rear power source wires 62C are formed so that one end thereof is continuous with the first power source terminals 62A, and the other end thereof is continuous with the upper side connecting portions 62B. To be specific, the first rear power source wires 62C are formed so as to extend from the first power source terminals 62A along the third power source wires 61C on the main body portion insulating base layer 31, the rear insulating base layer 33, the outer insulating base layer 34, and the inner-insulating base layer 36; bend outwardly in width direction at the rear end portion of the front-insulating base layer 35; thereafter bend frontward along the peripheral end of the front-insulating base layer 35 at the outer end thereof; and reach the upper side connecting portions 62B.

The first rear power source wires 62C electrically connect the first power source terminals 62A to the upper side connecting portions 62B.

In this manner, the light emitting element connection terminals 44 are electrically connected with the first power source terminals 62A through the first front power source wire 45, lower side connecting portion 43, via conductive portion 60, upper side connecting portions 62B, and first rear power source wires 62C. Then, through these, electric power is supplied from the power source for light emitting element (not shown) to the light emitting element 11.

The rear side portion of the first rear power source wires 62C is disposed on the upper face of the insulating base layer 3, and the front side portion is disposed on the upper face of the intermediate insulating layer 5. That is, the first rear power source wires 62C are formed so as to pass through the upper face of the insulating base layer 3 and on the upper face of the intermediate insulating layer 5. In the pedestal region, the first rear power source wires 62C are disposed on the upper face of the support insulating layer 55, and in the region other than the pedestal region, the first rear power source wires 62C are disposed on the upper face of the insulating base layer 3 or the intermediate insulating layer 5.

The magnetic head-connection circuit 63 includes, as shown in FIG. 2, signal terminals 63A, magnetic head-connection terminals 63B, and signal wires 63C.

The plurality of (four) signal terminals 63A are provided at the rear end portion of the main body portion insulating base layer 31. The signal terminals 63A are disposed two by two widthwise inner side of the plurality of (two) first power source terminals 62A and widthwise outer side of the plurality of (two) second power source terminals 46 in spaced apart relation from each other. The signal terminals 63A are electrically connected to a read/write substrate (not shown).

The plurality of (four) magnetic head-connection terminals 63B are provided, and are disposed at the widthwise center of the rear end portion of the intermediate insulating layer 5. That is, the magnetic head-connection terminals 63B are disposed at the front side of the slider mounting region 90 in plan view. The magnetic head-connection terminals 63B are formed into a generally rectangular shape extending in front-rear direction in plan view, and are disposed in spaced apart relation from each other in width direction. The magnetic head-connection terminals 63B are disposed, as shown in FIGS. 3 and 4, so that when projected in thickness direction, the magnetic head-connection terminals 63B overlap with the light emitting element connection terminal 44. To be specific, when projected in thickness direction, they are disposed so that of the four magnetic head-connection terminals 63B, the rear end portion of the inner two magnetic head-connection terminals 63B overlap with the light emitting element connection terminal 44.

The plurality of (four) signal wires 63C are provided, as shown in FIG. 2. The signal wires 63C are disposed two by two at the widthwise inner side of the plurality of (two) first rear power source wires 62C and at the widthwise outside of the plurality of (two) second power source wires 48 in spaced apart relation from each other in width direction. The signal wires 63C are formed so that one end thereof is continuous with the signal terminals 63A, and the other end thereof is continuous with the magnetic head-connection terminals 63B. To be specific, the signal wires 63C are formed so as to extend from the signal terminals 63A along the first rear power source wires 62C on the main body portion insulating base layer 31, rear insulating base layer 33, outer insulating base layer 34, and inner-insulating base layer 36; bend outwardly in width direction at the rear side portion of the front-insulating base layer 35; bend frontward at widthwise outside and extend frontward; extend frontward on the intermediate insulating layer 5, bend inwardly at its front end portion, and turn back to rear side at the inner portion; and reach the magnetic head-connection terminals 63B.

The signal wires 63C electrically connect the signal terminals 63A to the magnetic head-connection terminals 63B. The signal wires 63C transmit electric signals between the magnetic head 14 and the read/write substrate (not shown) through the signal terminals 63A.

The signal wires 63C are disposed such that its rear side portion is disposed on the upper face of the insulating base layer 3, and its front side portion is disposed on the upper face of the intermediate insulating layer 5. That is, the signal wires 63C are formed so as to pass through the upper face of the insulating base layer 3 and the upper face of the intermediate insulating layer 5. The signal wires 63C are disposed on the upper face of the support insulating layer 55 in the pedestal region.

In an embodiment, the wire whose portion at least of the wires is disposed on at least one upper face of the intermediate insulating layer 5 and the support insulating layer 55 is named the second wire of the present invention. In an embodiment, the wire whose entire wire is disposed on the upper face of the insulating base layer 3 is named the first wire of the present invention.

The second conductive pattern 6 is formed from a metal conductive material that is the same as the first conductive pattern 4, and preferably, it is formed from copper.

The second conductive pattern 8 has a thickness of; for example, 1 μm or more, preferably 3 μm or more, and for example, 25 μm or less, preferably 20 μm or less.

The wires (61C, 62C, 63C) have a width of, for example, 5 μm or more, preferably 8 μm or more, and for example, 200 μm or less, preferably 100 μm or less.

The space between the plurality of wires is, for example, 5 μm or more, preferably 8 μm or more, and for example, 1000 μm or less, preferably 100 μm or less.

The terminals (61A, 61B, 62A, 63A, 63B) have a width and a length (length in front-rear direction) of, for example, 10 μm or more, preferably 20 μm or more, and for example, 1000 μm or less, preferably 800 μm or less.

The upper side connecting portions 62B have a diameter of, for example, the same as the diameter of the lower side connecting portion 43.

The insulating cover layer 7 is disposed, as shown in FIGS. 3 to 6, on the upper face of the insulating base layer 3, first conductive pattern 4, intermediate insulating layer 5, support insulating layer 55, and second conductive pattern 6. To be specific, the insulating cover layer 7 is disposed on the upper face of the insulating base layer 3, intermediate insulating layer 5, and support insulating layer 55 so as to cover the upper face and the side faces of the wires (61C, 62C, 63C) of the second conductive pattern 6, and to expose the upper face of the terminals of rear end portion (first to third power source terminals 46, 61A, 62A, and signal terminals 62A).

The insulating cover layer 7 is formed so as to be generally the same with the insulating base layer 3 in plan view. That is, the insulating cover layer 7 integrally includes the main body portion insulating cover layer 71 corresponding to the main body portion insulating base layer 31, and the gimbal portion insulating cover layer 72 corresponding to the gimbal portion insulating base layer 32. The gimbal portion insulating cover layer 72 includes a pair of rear insulating cover layer 73 corresponding to the pair of rear insulating base layer 33, the pair of outer insulating cover layers 74 corresponding to the pair of outer insulating base layers 34, the front-insulating cover layer 75 corresponding to the front-insulating base layer 35, and the inner-insulating cover layer 76 corresponding to the inner-insulating base layer 36.

A rear cover insulating opening 77 corresponding to the rear insulating base opening 37 is opened between the main body portion insulating cover layer 71, a pair of rear insulating cover layers 73, a pair of outer insulating cover layers 74, and inner-insulating cover layer 76. The rear cover insulating opening 77 is disposed so as to include the main body opening 27 when projected in thickness direction.

A front cover insulating opening 78 corresponding to the front insulating base opening 38 is formed at a generally center of the front-insulating cover layer 75 in plan view. The front cover insulating opening 78 is formed into a generally rectangular shape in plan view so as to penetrate the front-insulating cover layer 75 in thickness direction when projected in thickness direction at the portion overlapping with the front opening 28. The front cover insulating opening 78 is formed so that is front end edge is positioned at the front side of the front end edge of the front insulating base opening 38 and the front end edge at widthwise center of the intermediate insulating layer 5, and coincides with the front end edge of the magnetic head-connection terminals 63B. In this manner, the front cover insulating opening 78 allow the magnetic head-connection terminals 63B disposed on the intermediate insulating layer 5 to be exposed from the insulating cover layer 7.

In the proximity of the front piezoelectric element connection terminal 61B, and the rear piezoelectric element connection terminal 47, the insulating cover layer 7 is formed so as to cover the upper face of these piezoelectric element connection terminals. To be specific, as shown in FIG. 3, the rear insulating cover layer 73 are formed so that its from end edge at the inner portion thereof is positioned at the front side of the front end edge of the inner portion of the rear insulating base layer 33, and coincide with the front end edge of the rear piezoelectric element connection terminal 47. The front-insulating cover layer 75 is formed so that rear-end edge of outer portion thereof is positioned at the rear side of the rear-end edge of outer portion of the front-insulating base layer 35, and coincides with the rear-end edge of the front piezoelectric element connection terminal 61B.

A plurality of (ten) terminal openings 79 are formed in the main body portion insulating cover layer 71, as shown in FIG. 3, so as to expose the upper face of the plurality of (ten) terminals. The terminal openings 79 are formed so as to be in spaced apart relation from each other in width direction. To be specific, the plurality of (two) terminal openings 79 that allow the upper face of the third power source terminals 61A to expose are formed at widthwise outermost side; the plurality of (two) terminal openings 79 that allow the upper face of the first power source terminal 62A to expose in widthwise inner side are formed in spaced apart relation; the plurality of (four) terminal openings 79 that allow the upper face of the signal terminals 63A to expose are formed its widthwise inner side in spaced apart relation; and the plurality of (two) terminal openings 79 that allow the upper face of the second power source terminals 46 to expose are formed at its widthwise inner side in spaced apart relation.

The insulating cover layer 7 is formed from the same insulating material as that is forming the insulating base layer 3. The insulating cover layer 7 has a thickness of, for example, 1 μm or more, preferably 3 μm or more, and for example, 40 μm or less, preferably 10 μm or less.

The pedestals 80 are described next. The pedestals 80 include, as shown in FIGS. 3 to 6, a plurality of (two) first pedestals 81 and a plurality of (two) second pedestals 82.

The first pedestals 81 are provided in the slider mounting region 90. To be specific, the first pedestals 81 are formed in correspondence with the first support insulating portions 56, and are formed in spaced apart relation from each other in width direction in the region of the rear end portion of the front-insulating cover layer 75.

The first pedestals 81 include the metal supporting board 2, insulating base layer 3, first support insulating portion 56, plurality of (four) wires (61C, 62C, 63C), and insulating cover layer 7 in this sequence. To be more specific, the first pedestals 81 include the mount portion 25, front-insulating base layer 35, first support insulating portion 56, plurality of (four) wires (61C, 62C, 63C), and front-insulating cover layer 75 in this sequence.

In the plurality of (four) wires, the third power source wire 61C, first rear power source wires 62C, and two signal wires 63C are arranged as the second wire in parallel in front-rear direction in spaced apart relation from each other.

In the upper portion (front-insulating cover layer 75) of the first pedestals 81, a plurality of (four) bumps 83 corresponding to the plurality of wires, and a plurality of (three) gaps 84 formed between the plurality of bumps 83 are formed.

The bumps 83 and the gaps 84 are formed so as to extend in width direction along the plurality of wires.

The second pedestals 82 are provided in the slider mounting region 90. To be specific, the second pedestals 82 are formed in correspondence with the second support insulating portions 57, and are formed in spaced apart relation from each other in width direction in the front end portion region of the inner-insulating cover layer 76.

The second pedestals 82 include the metal supporting board 2, insulating base layer 3, second support insulating portions 57, plurality of (four) wires (61C, 62C, 63C), and insulating cover layer 7 in this sequence. To be more specific, the second pedestals 82 include the connection portion 26, inner-insulating base layer 36, second support insulating portions 57, plurality of (four) wires (61C, 62C, 63C), and inner-insulating cover layer 76 in this sequence.

In the plurality of (four) wires, the third power source wire 61C, first rear power source wires 62C, and two signal wires 63C are arranged in parallel in spaced apart relation from each other in width direction.

In the upper portion (inner-insulating cover layer 76) of the second pedestals 82, a plurality of (four) bumps 83 corresponding to the plurality of wires, and a plurality of (three) gaps 84 formed between the plurality of bumps 83 are formed.

The bumps 83 and the gaps 84 are formed so as to extend in front-rear direction along the plurality of wires.

In the slider mounting region 90 of the suspension board with circuits 1, the region where the pedestals 80 are formed (pedestal region) is positioned higher in up-down direction than the region where the pedestals 80 are not formed. To be specific, in the slider mounting region 90, except for the pedestal region, the insulating layer such as the intermediate insulating layer 5 and the support insulating layer 55 are not included between the insulating base layer 3 and the insulating cover layer 7 in thickness direction.

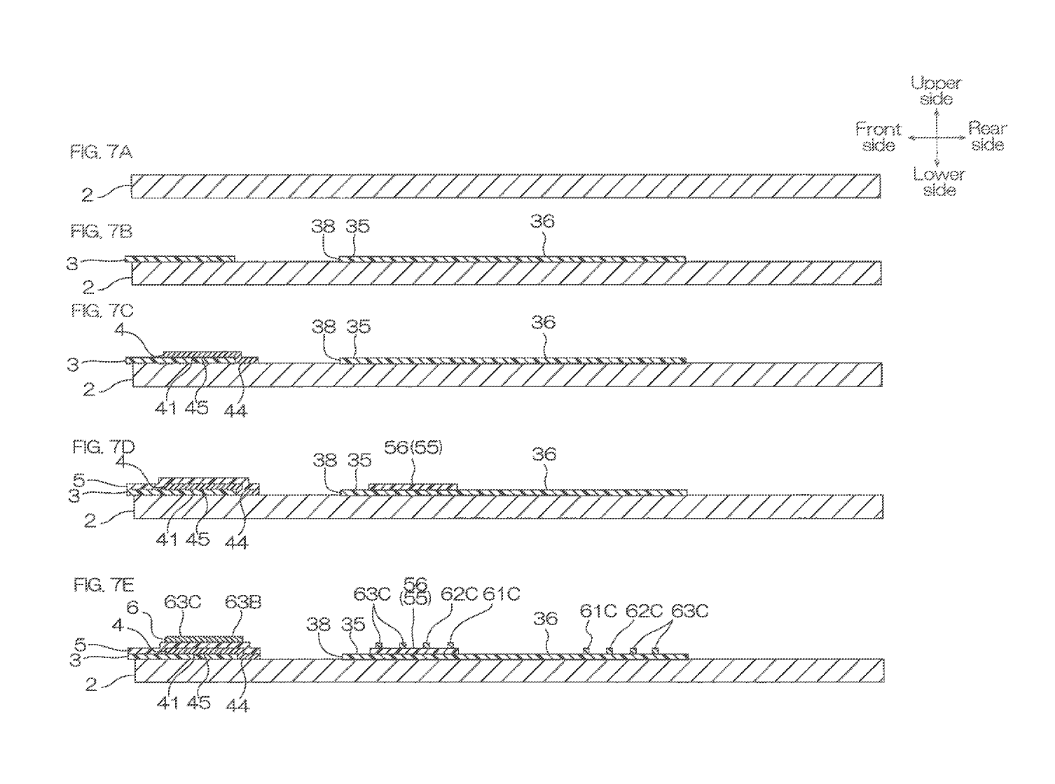

Next, description is given below of an embodiment of the method for producing a suspension board with circuits 1 with reference to FIG. 7A to FIG. 8I. FIG. 7A to FIG. 8H show step diagrams in cross sections taken along A-A side shown in FIG. 1, and FIG. 8I shows step diagrams in cross sections taken along B-B side shown in FIG. 1.

In this method, as shown in FIG. 7A, first, the metal supporting board 2 is prepared.

Then, as shown in FIG. 7B, the insulating base layer 3 is formed on the metal supporting board 2.

To be specific, the insulating base layer 3 is formed on the upper face of the metal supporting board 2 as a pattern corresponding to the main body portion insulating base layer 31, and the gimbal portion insulating base layer 32 (rear insulating base layer 33, outer insulating base layer 34, front-insulating base layer 35, and inner-insulating base layer 36).

To form the insulating base layer 3 including the main body portion insulating base layer 31 and the gimbal portion insulating base layer 32, varnish of a photosensitive insulating material is applied on the metal supporting board 2 and then dried to form a base film.

Thereafter, the base film is exposed to light through a photomask, which is not shown. The photomask includes a pattern of shield portion and total light transmittance portion. The photomask is disposed on the base film so that the total light transmittance portion faces the portion where the insulating base layer 3 is formed, and the shield portion faces the portion where the insulating base layer 3 is formed, and the base film is exposed to light.

Thereafter, the base film is developed, and as necessary heated to allow thermosetting, thereby forming the insulating base layer 3 including the pattern of the main body portion insulating base layer 31 and the gimbal portion insulating base layer 32.

Then, as shown in FIG. 7C, the first conductive pattern 4 is formed on the insulating base layer 3.

To be specific, the first conductive pattern 4 is formed on the upper face of the insulating base layer 3 and the metal supporting board 2 by a pattern forming method of additive method or subtractive method, preferably by additive method.

In this manner, as shown in FIG. 1, the first conductive pattern 4 including the light emitting element front connection circuit 41, and the rear piezoelectric element connection circuit 42 is formed. The light emitting element connection terminal 44 and the rear piezoelectric element connection terminal 47 are formed, as shown in FIGS. 4 and 5, so as to drop on the upper face of the metal supporting board 2.

Then, as shown in FIG. 7D, the intermediate insulating layer 5, and the support insulating layer 55 are formed on the insulating base layer 3.

To be specific, the intermediate insulating layer 5 is formed on the upper face of the front-insulating base layer 35 so as to cover the upper face and the side faces of the light emitting element connection terminal 44 and the first front power source wire 45. At this time, the intermediate insulating layer 5 is formed so as to form the plurality of (two) through holes 51 and expose the upper face of the lower side connecting portion 43.

Furthermore, the support insulating layer 55 is formed on the upper face of the front-insulating base layer 35 and the inner-insulating base layer 36 in the region forming the pedestals 80.

At this time, the intermediate insulating layer 5 and the support insulating layer 55 are formed simultaneously. That is, the intermediate insulating layer 5 and the support insulating layer 55 are formed in the same step as one insulating layer. The method for forming the intermediate insulating layer 5 and the support insulating layer 55 is the same as the method for forming the insulating base layer 3.

Then, as shown in FIG. 7E, the second conductive pattern 6 is formed on the intermediate insulating layer 5 and the support insulating layer 55.

To be specific, the second conductive pattern 6 is formed on the upper face of the intermediate insulating layer 5, support insulating layer 55, insulating base layer 3, and metal supporting board 2 by a pattern forming method of additive method or subtractive method, preferably by additive method. At this time, the front piezoelectric element connection terminal 61B of the second conductive pattern 6 is formed so as to drop on the upper face of the metal supporting board 2, as shown in FIG. 5.

In this manner, as shown in FIG. 1, the second conductive pattern 6 is formed so as to include the front piezoelectric element connection circuit 61, light emitting element rear side connection circuit 62, and magnetic head-connection circuit 63.

At the same time with forming the second conductive pattern 6, the through hole 51 is filled with the same material as that of the second conductive pattern 6 to form the via conductive portion 60.

Then, as shown in FIG. 8F, the insulating cover layer 7 is formed on the first conductive pattern 4, second conductive pattern 6, intermediate insulating layer 5, and support insulating layer 55.

To be specific, the insulating cover layer 7 is formed on the first conductive pattern 4, second conductive pattern 6, intermediate insulating layer 5, and support insulating layer 55 as a pattern corresponding to the main body portion insulating cover layer 71, and the gimbal portion insulating cover layer 72 (rear insulating cover layer 73, outer insulating cover layer 74, front-insulating cover layer 75, and inner-insulating cover layer 76).

At this time, the insulating cover layer 7 is formed so as to expose the upper face and the side faces of the magnetic head-connection terminals 63B. The insulating cover layer 7 is formed in the main body portion insulating cover layer 71 so as to form the plurality of (ten) terminal openings 79. Meanwhile, the insulating cover layer 7 is formed so as to cover the upper face and the side faces of the front piezoelectric element connection terminal 61B, and the rear piezoelectric element connection terminal 47.

Then, as shown in FIG. 8G, the metal supporting board 2 is trimmed so that the main body opening 27, front opening 28, and center opening 29 are formed by, for example, etching.

Then, as necessary, a plated layer is formed on the surface of the plurality of terminals. To be specific, a plated layer, which is not shown, is formed by plating such as electroless plating and electrolytic plating, preferably by, electrolytic plating.

In this manner, the suspension board with circuits 1 is completed.

As shown in FIG. 8H and FIG. 8I, the slider unit 12 and the plurality of (two) piezoelectric elements 13 are mounted on the suspension board with circuits 1.

As shown in FIG. 8H, the slider unit 12 includes the slider 10 and the light emitting element 11.

The slider 10 is formed into a generally rectangular box shape in plan view, and a magnetic head 14 is mounted on the slider 10. The magnetic head 14 is provided at the front end portion of the slider 10, for reading and writing on a magnetic disk, which is not shown. A head-side terminal 15 is formed at the lower side portion of the front end portion of the magnetic head 14.

The light emitting element 11 is formed into a generally rectangular shape in plan view, having a smaller contour than that of the slider 10. The light emitting element 11 is provided at the lower face of the front side in front-rear direction of the slider 10. The light emitting element 11 is a heat-assisted device including, for example, laser diode, and can heat recording face of magnetic disk, which is not shown, by laser beam. The light emitting element-side terminal 16 is formed at the lower side portion of the front end portion of the light emitting element 11.

Upon mounting the slider unit 12, first, the slider unit 12 is disposed on the slider mounting region 90. To be specific, the slider unit 12 is disposed from above the suspension board with circuits 1 so that the light emitting element 11 is inserted in the front opening 28.

At this time, the slider 10 is mounted on the first pedestals 8 and the second pedestals 82. That is, the lower face of the slider 10 contacts the plurality of first pedestals 81 and the plurality of second pedestals 82, and the portion of the suspension board with circuits 1 other than the first pedestals 81 and the second pedestals 82 do not contact the slider 10.

At this time, an adhesive (shown in the figure) is disposed between the first pedestals 81 and second pedestals 82, and the slider 10. In this manner, the slider unit 12 and the suspension board with circuits 1 are fixed.

Then, a first joint material 19 is disposed between the head-side terminal 15 and the magnetic head-connection terminals 63B, and between the light emitting element-side terminal 16 and the light emitting element connection terminal 44, and thereafter heating such as reflowing is performed.

Examples of the first joint material 19 include conductive materials such as solder and conductive adhesive (for example, silver paste, etc.).

In this manner, the first joint material 19 melts and flows, and then solidified. As a result, the magnetic head-connection terminals 63B are electrically connected to the head-side terminal 15 of the magnetic head 14, and the light emitting element connection terminal 44 is electrically connected to the light emitting element-side terminal 16 of the light emitting element 11.

As shown in FIG. 8I, a pair of piezoelectric elements 13 are actuators capable of expansion and contraction in front-rear direction, and are formed into a generally rectangular shape in plan view extending in front-rear direction. Expansion and contraction of the piezoelectric element 13 allow for subtle adjustment of the positions of the gimbal portion 22, and the slider unit 12. The piezoelectric element-side front terminal 17 and the piezoelectric element-side rear side terminal 18 are formed on the front end portion and the rear end portion of the upper face of the piezoelectric element 13, respectively.

Upon mounting the piezoelectric element 13, first, the piezoelectric element 13 is disposed on the piezoelectric element mounting region 91. To be specific, the piezoelectric element 13 is disposed from below the suspension board with circuits 1 so as to be included in the center opening 29 when projected in thickness direction.

Then, a second joint material 20 is disposed between the piezoelectric element-side front terminal 17 and the front piezoelectric element connection terminal 61B, and between the piezoelectric element-side rear side terminal 18 and the rear piezoelectric element connection terminal 47, and thereafter, heating such as reflowing is performed.

For the second joint material 20, those conductive materials given as examples of the first joint material 19 are used.

In this manner, the second joint material 20 melts and flows, and then solidified. As a result, the piezoelectric element-side front terminal 17 and the front piezoelectric element connection terminal 61B are electrically connected, and the piezoelectric element-side rear side terminal 18 and the rear piezoelectric element connection terminal 47 are electrically connected.

The piezoelectric element 13 is fixed on the lower face of the suspension board with circuits 1 across the front piezoelectric element connection terminals 61B and the rear piezoelectric element connection terminals 47.

The suspension board with circuits 1 includes the insulating base layer 3, intermediate insulating layer 5, insulating cover layer 7, support insulating layer 55, first conductive pattern 4, and second conductive pattern 6. The first conductive pattern 4 includes the light emitting element connection terminal 44 and the first wire (first front connection wire 45), and the second conductive pattern 6 includes the magnetic head-connection terminals 63B and the second wires (third power source wire 61C, first rear power source wires 62C, and signal wires 63C). The pedestals 80 supporting the slider unit 12 are also included.

Thus, the slider unit 12 including the light emitting element 11 and the slider 10 can be mounted.

The pedestals 80 include the insulating base layer 3, support insulating layer 55, plurality of second wires (third power source terminal 61C, first rear power source wires 62C, and signal wires 63C), and insulating cover layer 7 in this sequence. That is, the support insulating layer 55 and the plurality of second wires are provided in this sequence between the insulating base layer 3 and the insulating cover layer 7.

Therefore, in the slider mounting region 90, the position of the region where the support insulating layer 55 is provided (pedestal region) can be made higher than the other regions, and the region where the support insulating layer 55 is provided also can work as the pedestal.

Also, a front-side support layer for supporting the slider unit 12 does not have to be provided on the upper side of the insulating cover layer 7. Upon forming the intermediate insulating layer 5, the support insulating layer 55 can be formed simultaneously, and therefore the number of the insulating layer for supporting the slider unit 12 does not have to be increased.

Thus, increase in thermal hysteresis for forming the support insulating layer for sliders can be suppressed, and reliability of the suspension board with circuits 1 can be kept.

Furthermore, in the region where the second wires are formed, the pedestals 80 (first pedestals 81, second pedestals 82) can be provided, and therefore a dedicated space for disposing the pedestals 80 does not have to be provided. Thus, degree of freedom in disposing the pedestals 80 and wires improves.

On the pedestals 80, the insulating cover layer 7 is disposed on the plurality of second wires, and therefore on the upper portion of the pedestals 80, a plurality of bumps 83 extending along the plurality of second wires are formed.

In this manner, the slider unit 12 can be mounted on the plurality of elongated bumps 83, and therefore the slider unit 12 can be supported stably.

Furthermore, in the pedestals 80, the insulating cover layer 7 is disposed on the plurality of second wires, and therefore gaps 84 along the plurality of second wires are formed on the upper portion of the pedestals 80. Therefore, even if adhesive is excessively supplied on the pedestals 80, the excessive adhesive can be discharged from the region of the pedestals 80 along the gaps 84. That is, positioning failure of the slider unit 12 due to staying of the excessive adhesive can be suppressed. Also, because sufficient adhesive can be disposed on the pedestals 80, the slider unit 12 can be fixed on the pedestals 80 reliably.

The suspension board with circuits 1 includes the metal supporting board 2 below the insulating base layer 3. Therefore, the slider unit 12 can be supported even more reliably with the metal supporting board 2.

In the suspension board with circuits 1, the first pedestals 81 and the second pedestals 82 are disposed so that they cross each other. Therefore, the slider unit 12 can be stably supported against the stress from the front-rear direction and width direction.

### Modified Example of First Embodiment

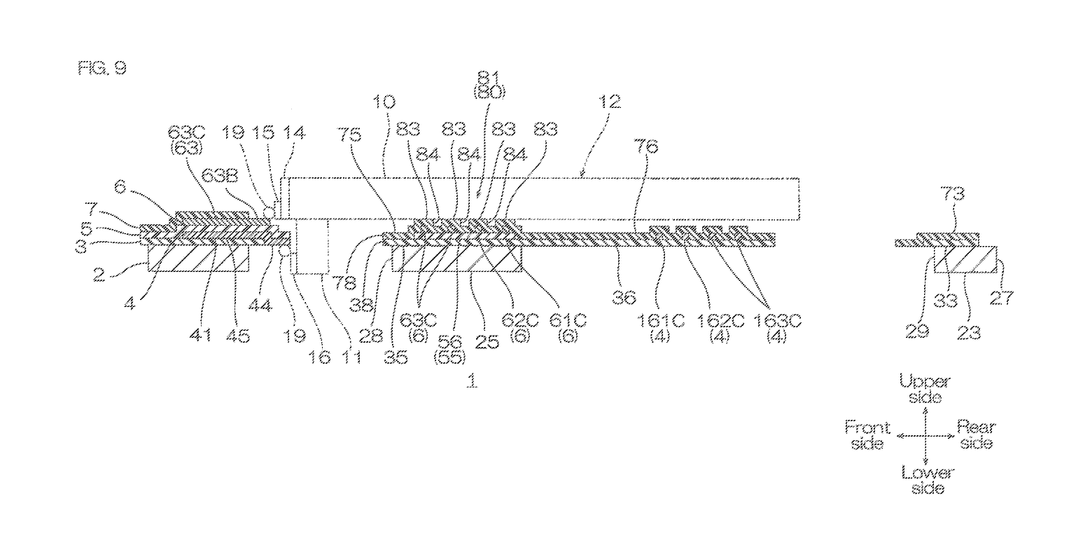

In the embodiment shown in FIG. 4, the plurality of wires (third power source terminal 61C, first rear power source wires 62C, and signal wires 63C) (wire not forming the pedestals 80) disposed in the rear side portion of the slider mounting region (for example, rear end portion of inner-insulating base layer 36) are formed as the second conductive pattern 6. That is, these wires are formed simultaneously with the plurality of wires (61C, 62C, 63C) forming the pedestals 80, but for example, as shown in FIG. 9, the plurality of wires (wire not forming the pedestals 80) disposed at the rear end portion of the inner-insulating base layer 36 can also be formed as the first conductive pattern 4.

That is, the first conductive pattern 4 further includes the first conductive pattern-third power source wire 161C, first conductive pattern-first rear power source wire 162C, and first conductive pattern-signal wire 163C.

In this embodiment, the terminals (first to third power source terminals and signal terminals) formed in the main body portion 21 are also formed simultaneously with the light emitting element front connection circuit 41 and rear piezoelectric element connection circuit 42 at the time of production processes as the first conductive pattern 4.

In this embodiment, with suitable wiring design, the first conductive pattern 4 (first conductive pattern-third power source wire 161C, first conductive pattern-first rear power source wire 162C, and first conductive pattern-signal wire 163C) is electrically connected to the second conductive pattern 6 (third power source wire 61C, first rear power source wires 62C and signal wires 63C), respectively, through the via structure (lower side connecting portion, via conductive portion, and upper side conductive portion).

In the production processes, the rear piezoelectric element connection circuit 42 is formed simultaneously with the light emitting element front connection circuit 41, that is the first conductive pattern 4, but for example, although not shown, the rear piezoelectric element connection circuit 42 can be formed simultaneously with the second conductive pattern 6.

### Second Embodiment

With reference to FIG. 10 to FIG. 13, the suspension board with circuits 1 in the second embodiment is described. In the second embodiment, those members that are the same as those in first embodiment described above are given the same reference numerals, and description thereof is omitted.

In the first embodiment, the pedestals 80 include the insulating base layer 3, support insulating layer 55, plurality of second wires, and insulating cover layer 7 in this sequence, but in the second embodiment, as shown in FIGS. 10 to 13, the pedestals 80 include the insulating base layer 3, plurality of first wires, support insulating layer 55, and insulating cover layer 7 in this sequence.

To be specific, in the second embodiment, as shown in FIG. 10, the first conductive pattern 4 includes the light emitting element connection circuit 262, magnetic head rear side connection circuit 263, front piezoelectric element connection circuit 261, and rear piezoelectric element connection circuit 42.

The light emitting element connection circuit 262 includes the first power source terminal 62A, light emitting element connection terminal 44, and first power source wire 262C.

A plurality of (two) first power source wires 262C are provided. The first power source wires 262C are disposed one by one adjacently widthwise inner side of the plurality of (two) third power source wires 61C in spaced apart relation from each other in width direction. The first power source wires 262C are formed so that one end thereof is continuous with the first power source terminal 62A, and the other end thereof is continuous with the light emitting element connection terminal 44. To be specific, the first power source wire 262C are formed so as to extend frontward from the first power source terminal 62A in the main body portion insulating base layer 31; bend widthwise outwardly on the front end portion of the main body portion insulating base layer 31; bend frontward on the both widthwise end portions; extend frontward on the rear insulating base layer 33 and the outer insulating base layer 34; bend widthwise inwardly on the front end portion of the outer insulating base layer 34; bend frontward at widthwise center of the inner-insulating base layer 36; bend outwardly in width direction, bend frontward and extend frontward at widthwise outside on the rear end portion of the front-insulating base layer 35; extend frontward on the intermediate insulating layer 5; bend inwardly at its front end portion; turn back to rear side at inner portion; and reach the light emitting element connection terminal 44.

The first power source wire 262C electrically connects the first power source terminal 62A to the light emitting element connection terminal 44.

The magnetic head rear side connection circuit 263 includes the signal terminals 63A, lower side connecting portion 43, and rear signal wire 263C.

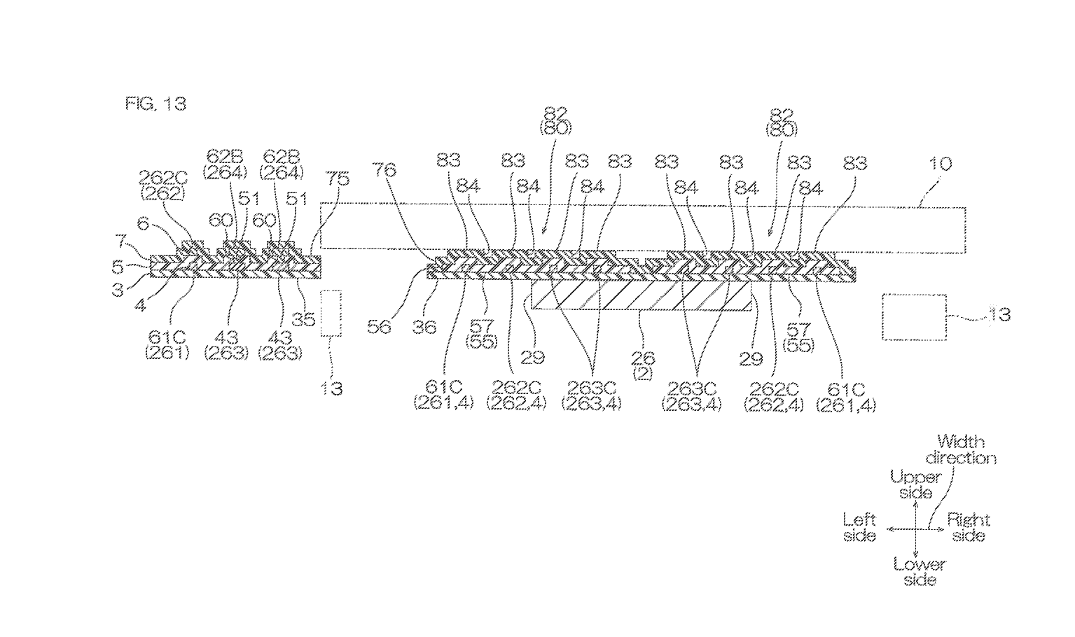

A plurality of (four) lower side connecting portions 43 are provided, and are disposed two by two widthwise outside at the front side portion of the front-insulating base layer 35 in spaced apart relation from each other in width direction. The lower side connecting portions 43 are formed into a generally circular shape (circle land shape) in plan view, and are disposed so as to include the through hole 51 when projected in thickness direction. The upper end portion of the lower side connecting portions 43 is continuous with, as shown in FIG. 13, the lower end of the via conductive portion 60.

A plurality of (four) rear signal wires 263C are provided. The rear signal wires 263C are disposed two by two widthwise inner side of the plurality of (two) first power source wires 262C, and widthwise outside of the plurality of (two) second power source wires 48 in spaced apart relation from each other in width direction. The rear signal wires 263C are formed so that one end thereof is continuous with the signal terminals 63A, and the other end thereof is continuous with the lower side connecting portions 43. To be specific, the rear signal wires 263C are formed so as to extend from the signal terminals 63A along the first power source wire 262C on the main body portion insulating base layer 31, rear insulating base layer 33, outer insulating base layer 34, inner-insulating base layer 36, and front-insulating base layer 35; and reach the lower side connecting portions 43 at widthwise outside of the front side portion of the front-insulating base layer 35.

The rear signal wires 263C electrically connect signal terminals 63A to the lower side connecting portions 43.

The front piezoelectric element connection circuit 261 includes the third power source terminal 61A, front piezoelectric element connection terminal 61B, and third power source wire 61C.

The rear piezoelectric element connection circuit 42 includes the second power source terminals 46, rear piezoelectric element connection terminal 47, and second power source wire 48.

The intermediate insulating layer 5 is disposed at, as shown in FIGS. 11 to 13, the upper face of the insulating base layer 3 and the first conductive pattern 4. To be specific, the intermediate insulating layer 5 is disposed on the upper face of the insulating base layer 3 so as to cover the upper face and side faces of the first power source wire 262C and rear signal wire 263C on the front side portion.

Plurality of (four) through holes 51 penetrating the intermediate insulating layer 5 in thickness direction are formed in the intermediate insulating layer 5, as shown in FIG. 13. The through holes 51 are disposed two by two at widthwise outside portion of the intermediate insulating layer 5 in spaced apart relation from each other in width direction. The through holes 51 are formed into a generally circular shape in plan view having a smaller diameter than that of the lower side connecting portions 43 when projected in thickness direction at the portion overlapping with the lower side connecting portions 43. Via conductive portions 60 are provided in the through holes 51.

The support insulating layer 55 is disposed, as shown in FIG. 11, in the slider mounting region 90, on the upper face of the insulating base layer 3 and the first conductive pattern 4. The support insulating layer 55 include a plurality of (four) support insulating portions. That is, the support insulating layer 55 includes a plurality of (two) first support insulating portions 56 and a plurality of (two) second support insulating portions 57 disposed at the rear side thereof.

The plurality of first support insulating portions 56 are disposed in spaced apart relation in width direction at the rear side portion of the front-insulating base layer 35. The first support insulating portions 56 are formed into a sheet extending in surface direction. The first support insulating portions 56 are disposed so as to overlap with the plurality of (four) wires (61C, 262C, 263C) when projected in thickness direction. To be specific, the first support insulating portions 56 are formed into a generally rectangular shape in plan view extending in front-rear direction crossing the plurality of wires (orthogonal), and are disposed on the upper face of the front-insulating base layer 35 so as to cover the upper face and side faces of the plurality of wires (61C, 262C, 263C). That is, the first support insulating portions 56 are disposed on the upper side of the wires across the plurality of (four) wires (61C, 62C, 63C) in front-rear direction.

The plurality of second support insulating portions 57 are disposed in spaced apart relation in width direction at the front side portion of the inner-insulating base layer 36. The second support insulating portions 57 are formed into a sheet shape extending in surface direction.

The second support insulating portions 57 are disposed so as to overlap, when projected in thickness direction, the plurality of (four) wires (61C, 262C, 263C). To be specific, the second support insulating portions 57 are formed into a generally rectangular shape in plan view extending in width direction crossing the plurality of wires (orthogonal), and are disposed on the upper face of the inner-insulating base layer 36 so as to cover the upper face and the side faces of the plurality of wires (61C, 262C, 263C). That is, the second support insulating portions 57 are disposed on the upper side of these wires across the plurality of (four) wires (61C, 62C, 63C) in width direction.

The second conductive pattern 6 is disposed on the upper face of the intermediate insulating layer 5. The second conductive pattern 6 includes a magnetic head front connection circuit 264.

The magnetic head front connection circuit 264 includes upper side connecting portions 62B, magnetic head-connection terminals 63B, and front signal wire 2642 as a second wire.

The plurality of (four) upper side connecting portions 62B are provided, and are disposed two by two in spaced apart relation from each other in width direction at widthwise outside of the intermediate insulating layer 5. The upper side connecting portions 62B are formed into a generally circular shape (circle land shape) in plan view, and are disposed so as to include the through hole 51 (described later) when projected in thickness direction. The lower end portion of the upper side connecting portions 62B is continuous with, as shown in FIG. 13, upper end of the via conductive portion 60.

As shown in FIG. 11, the plurality of (four) front signal wire 264C are provided two by two on the intermediate insulating layer 5 in spaced apart relation from each other in width direction. The front signal wire 264C are formed so that one end thereof is continuous with the upper side connecting portions 62B, and the other end thereof is continuous with the magnetic head-connection terminals 63B. To be specific, the front signal wire 264C are formed so as to slightly extend from the upper side connecting portions 62B to the front side at the rear side portion of the widthwise outside of the intermediate insulating layer 5; bend inwardly at its front end portion; turn back to rear side at inner portion; and reach the magnetic head-connection terminals 63B.

The front signal wire 264C electrically connect the upper side connecting portions 62B to the magnetic head-connection terminals 63B.

In this manner, the magnetic head-connection terminals 63B are electrically connected to the signal terminals 63A through the front signal wire 264C, upper side connecting portions 62B, via conductive portion 60, lower side connecting portions 43, and rear signal wire 263C.

Then, through these, the magnetic head 14 and the read/write substrate (not shown) transmit electric signals therebetween.

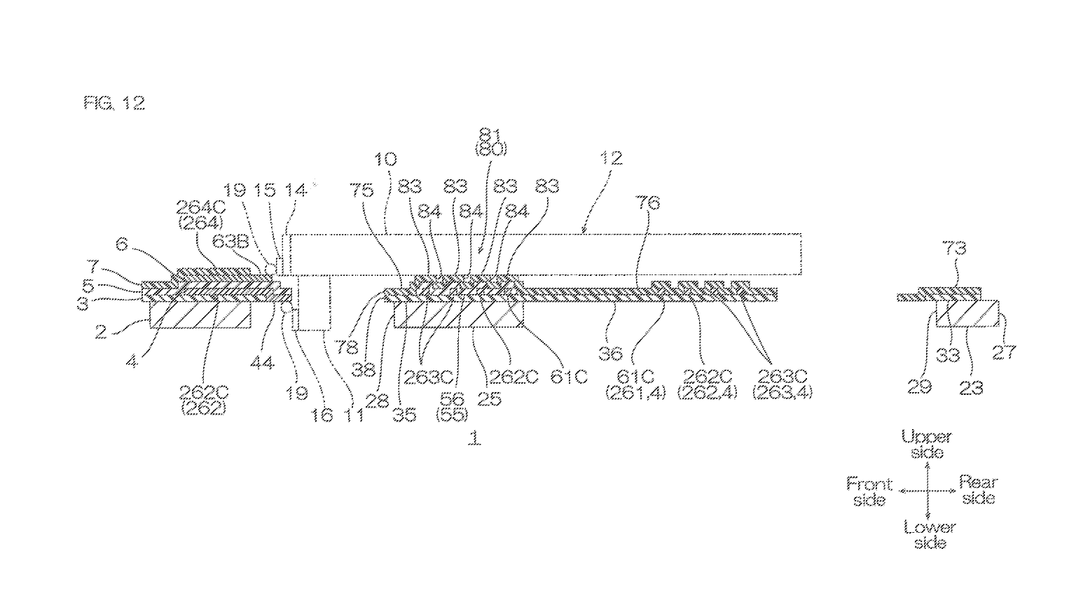

The pedestals 80 include, as shown in FIGS. 12 to 13 (ref: FIG. 3), a plurality of (two) first pedestals 81 and a plurality of (two) second pedestal 82.

The first pedestals 81 are provided in the slider mounting region 90. The first pedestals 81 include the metal supporting board 2, the insulating base layer 3, plurality of (four) wires (61C, 262C, 263C), first support insulating portions 56, and insulating cover layer 7 in this sequence. To be more specific, the first pedestals 81 include the mount portion 25, front-insulating base layer 35, plurality of (four) wires (61C, 262C, 263C), first support insulating portions 56, and front-insulating cover layer 75 in this sequence.

The plurality of (four) wires include the first wire of third power source wire 61C, first power source wire 262C, and rear signal wire 263C arranged in parallel in spaced apart relation from each other in front-rear direction.

At the upper portion (front-insulating cover layer 75) of the first pedestals 81, a plurality of (four) bumps 83 corresponding to the plurality of wires, and a plurality of (three) gaps 84 formed between the plurality of bumps 83 are formed.

The bumps 83 and gaps 84 are formed so as to extend in width direction along the plurality of wires.

The second pedestals 82 are provided in the slider mounting region 90. The second pedestals 82 include the metal supporting board 2, insulating base layer 3, plurality of (four) wires (61C, 262C, 263C), second support insulating portions 57, and insulating cover layer 7 in this sequence. To be more specific, the second pedestals 82 include the connection portion 26, inner-insulating base layer 36, second support insulating portions 57, plurality of (four) wires (61C, 262C, 263C), and inner-insulating cover layer 76 in this sequence.

The plurality of (four) wires include the third power source wire 61C, first power source wire 262C, and rear signal wire 263C arranged in parallel in spaced apart relation from each other in width direction.

At the upper portion (inner-insulating cover layer 76) of the second pedestals 82, a plurality of (four) bumps 83 corresponding to the plurality of wires, and a plurality of (three) gaps 84 formed between the plurality of bumps 83 are formed.

The bumps 83 and gaps 84 are formed so as to extend in front-rear direction along the plurality of wires.

The suspension board with circuits 1 in the second embodiment includes the insulating base layer 3, intermediate insulating layer 5, insulating cover layer 7, first conductive pattern 4, and second conductive pattern 6. The first conductive pattern 4 includes the light emitting element connection terminal 44 and first wires (third power source wire 61C, first power source wire 262C, and rear signal wire 263C), and the second conductive pattern 6 includes the magnetic head-connection terminals 63B and second wire (front signal wire 264C). The pedestals 80 supporting the slider unit 12 are also included.

The pedestals 80 include the insulating base layer 3, plurality of first wires (third power source wire 61C, first power source wire 262C, and rear signal wire 263C), support insulating layer 55, and insulating cover layer 7 in this sequence. That is, the plurality of first wires and support insulating layer 55 are provided in this sequence between the insulating base layer 3 and insulating cover layer 7.

The suspension board with circuits 1 in the second embodiment also have the same operations and effects as those of the first embodiment. That is, increase in thermal hysteresis for forming the support insulating layer for sliders can be suppressed, and reliability of the suspension board with circuits 1 can be kept. Furthermore, there is no need to provide a dedicated space for disposing pedestals, and therefore degree of freedom in disposing pedestals and wires improves. Also, the plurality of bumps 83 extending along the plurality of first wires are formed at the upper portion of the pedestals 80, and therefore the slider unit 12 can be stably supported. The bumps 83 along the plurality of first wire are formed at the upper portion of the pedestals 80, and therefore positioning failure of the slider unit 12 can be suppressed, and reliable fixing of the slider unit 12 to the pedestals 80 can be achieved. Furthermore, because the metal supporting board 2 is included below the insulating base layer 3, and therefore the slider unit 12 can be supported by the metal supporting board 2 even more reliably.

### Modified Example of Second Embodiment

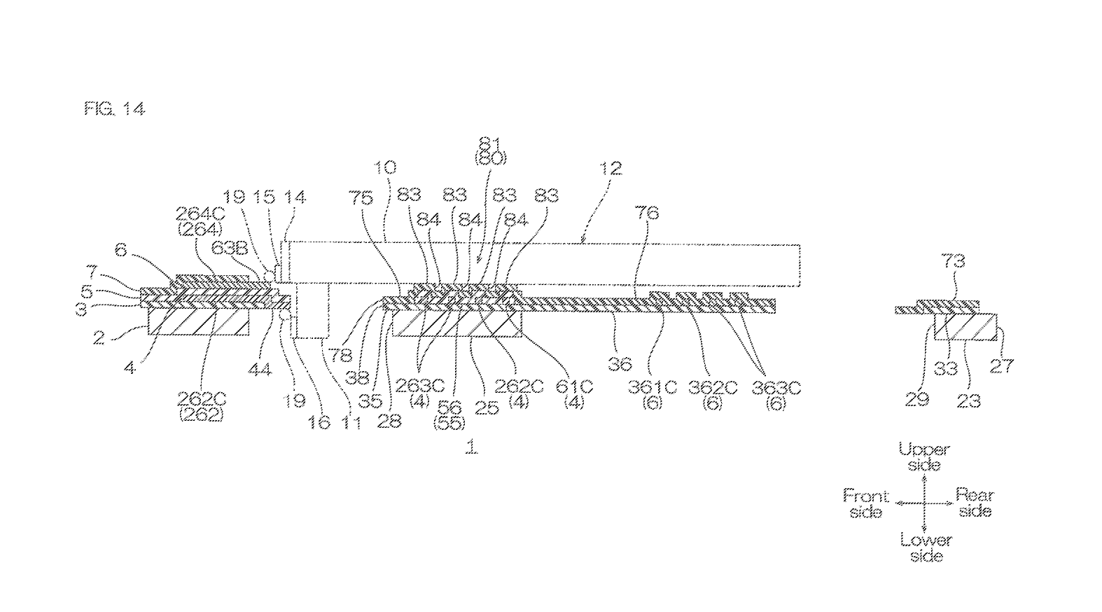

In the embodiment shown in FIG. 12, the plurality of wires (third power source wire 61C, first power source wire 262C, and rear signal wire 263C)(wire not forming the pedestals 80) are disposed in the rear side portion of the slider mounting region (for example, rear end portion of the inner-insulating base layer 36) as the first conductive pattern. That is, these wires are formed simultaneously with the plurality of wires (61C, 262C, 263C) forming the pedestals 80, but for example, as shown in FIG. 14, the plurality of wires (wire not forming the pedestals 80) disposed at the rear end portion of the inner-insulating base layer 36 can also be formed as the second conductive pattern 6.

That is, the second conductive pattern 6 further includes the second conductive pattern-third power source wire 361C, second conductive pattern-first power source wire 362C, and second conductive pattern-rear signal wire 363C.

In this case, the terminals formed in the main body portion 21 (first to third power source terminals, and signal terminals) are formed simultaneously as the second conductive pattern at the time of production processes with the magnetic head front connection circuit 264.

In this embodiment, with suitable wiring design, the second conductive pattern-third power source wire 361C, second conductive pattern-first power source wire 362C, and second conductive pattern-rear signal wire 363C are electrically connected to the first conductive pattern 4 (third power source wire 61C, first power source wire 262C, and rear signal wire 263) through the via structure.

In the production processes, the rear piezoelectric element connection circuit 42 is formed simultaneously with the light emitting element connection circuit 262, that is the first conductive pattern 4, but for example, although not shown, the rear piezoelectric element connection circuit 42 can be formed simultaneously with the second conductive pattern 6.

### Other Modified Example

In the first embodiment and second embodiment, the first pedestals 81 and second pedestals 82 include the plurality of (four) wires, but the number of wires is not limited, and for example, 2, 3, or 5 or more wires can be included.

In the first embodiment and second embodiment, the number of the pedestals is, for the first pedestals 81 and second pedestals 82, two each, but the number of the pedestals is not limited. For example, one first pedestal 81 only can be included, and one second pedestals 82 only can be included, and furthermore, three or more first pedestals 81 and second pedestals 82 can be included.

In the first embodiment and second embodiment, the shape of the pedestals 80, and the support insulating layer 55 (first support insulating portions 56 and second support insulating portions 57) is a generally rectangular shape in plan view, but the shape is not limited, and for example, it can be a generally oval shape in plan view.

While the illustrative embodiments of the present invention are provided in the above description, such is for illustrative purpose only and it is not to be construed as limiting in any manner. Modification and variation of the present invention that will be obvious to those skilled in the art is to be covered by the following claims.

1. A suspension board with circuits, wherein a slider and an electronic component can be mounted thereon, the suspension board with circuits comprising:
a first insulating layer,
a second insulating layer disposed on the first insulating layer,
a third insulating layer disposed on the second insulating layer,
a first conductive layer including an electronic component-connection terminal for electrically connecting with the electronic component, and a first wire disposed on the first insulating layer, and
a second conductive layer including a magnetic head-connection terminal for electrically connecting with a magnetic head provided in the slider, and a second wire, wherein at least a portion of the second wire is disposed on the second insulating layer,
wherein the suspension board with circuits has a pedestal supporting the slider,
the pedestal includes
the first insulating layer,
the second insulating layer,
the third insulating layer, and
one of the first wire and the second wire.

2. The suspension board with circuits according to claim 1, wherein the second conductive layer includes a plurality of second wires,
the pedestal includes the first insulating layer, the second insulating layer, the plurality of second wires, and the third insulating layer in sequence.

3. The suspension board with circuits according to claim 1, wherein the first conductive layer includes a plurality of first wires, and
the pedestal includes the first insulating layer, the plurality of first wires, the second insulating layer, and the third insulating layer.
